(19) United States
(12) Patent Application Publication
(10) Pub. No.: US 2024/0341163 A1
(43) Pub. Date: Oct. 10, 2024

(54) ANTI-SHOCK LAYER AND DISPLAY PANEL INCLUDING THE SAME

(71) Applicant: Samsung Display Co., Ltd., Yongin-si (KR)

(72) Inventors: SUNGEUN LEE, Yongin-si (KR); YOUN JOON KIM, Yongin-si (KR); MINJEONG OH, Yongin-si (KR); KIJUNE LEE, Yongin-si (KR); JINHO JU, Yongin-s (KR); JONGHYUN CHOI, Yongin-si (KR)

(21) Appl. No.: 18/395,921

(22) Filed: Dec. 26, 2023

(30) Foreign Application Priority Data
Apr. 5, 2023 (KR) 10-2023-0045006

(51) Int. Cl. H10K 77/10; H10K 59/121; H10K 59/131; H10K 102/00; H10K 102/20

(52) U.S. Cl. CPC H10K 77/111; H10K 59/1213; H10K 59/131; H10K 2102/20; H10K 2102/311

(57) ABSTRACT

A display panel includes a display area, a circuit element layer including insulating layers and a transistor in the display area, a first insulating layer among the insulating layers defining a first through hole of the circuit element layer which is in the display area, a light emitting element electrically connected to the transistor, and an anti-shock pattern having an elastic modulus greater than about 100 gigapascals, the anti-shock pattern being in the first through hole.

This application claims priority to Korean Patent Application No. 10-2023-0045006, filed on Apr. 5, 2023, and all the benefits accruing therefrom under 35 U.S.C. § 119, the contents of which are hereby incorporated by reference in its entirety.

### BACKGROUND

### 1. Field

The present disclosure relates to a display panel. More particularly, the present disclosure relates to a flexible display panel.

### 2. Description of the Related Art

Multimedia electronic devices, such as televisions, mobile phones, tablet computers, navigation devices, and game devices, include a display device displaying an image. The display device includes a display panel generating the image and providing a user with the generated image. The display panel includes pixels generating the image and a driver driving the pixels.

With the technological development of the display device, a flexible display device including a flexible display panel is being developed. For example, various flexible display devices, which are foldable, rollable, or capable of being transformed into a curved shape, are being developed. The flexible display devices are easy to carry and improve a user's convenience.

However, since the flexible display panel is vulnerable to external impacts, transistors are damaged due to external impacts or stress caused by a folding operation, and as a result, the pixels are malfunctioned.

### SUMMARY

The present disclosure provides a display panel with improved impact resistance and reliability.

Embodiments of the invention provide a display panel including a base substrate including a display area, a circuit element layer disposed on the base substrate and including insulating layers and a transistor, a light emitting element disposed on the circuit element layer and electrically connected to the transistor, and an anti-shock portion disposed in a through hole defined through at least a portion of the insulating layers in the display area. The anti-shock portion has a modulus equal to or greater than about 100 gigapascals (GPa).

The anti-shock portion may include a metal material.

The insulating layer through which the through hole is defined among the insulating layers may include an inorganic layer.

The transistor may include a semiconductor pattern disposed on the base substrate and including a source, a channel, and a drain and a gate electrode disposed on the semiconductor pattern, and the anti-shock portion does not overlap the source and the drain.

The circuit element layer further may include a connection electrode electrically connecting the transistor and the light emitting element, and the anti-shock portion is disposed on the same layer as the connection electrode.

The anti-shock portion may include the same material as the connection electrode.

The circuit element layer further may include sub-scan lines disposed on different layers from each other and overlapping each other, and the sub-scan lines receive the same signal.

The anti-shock portion may overlap the sub-scan lines.

The display panel further may include a shock absorption pattern disposed penetrating at least a portion of the insulating layers in the display area, and the shock absorption pattern may include an organic material.

The shock absorption pattern may surround some areas of the circuit element layer when viewed in a plane.

The shock absorption pattern may have a modulus lower than a modulus of the anti-shock portion.

Embodiments of the invention provide a display panel including a base substrate, a plurality of insulating layers disposed on the base substrate, a first semiconductor pattern layer disposed on the base substrate, a first conductive pattern layer disposed on the first semiconductor pattern layer, a second conductive pattern layer disposed on the first conductive pattern layer, a light emitting element disposed on the second conductive pattern layer, and an anti-shock portion disposed between the base substrate and the light emitting element and having a modulus equal to or greater than about 100 GPa. The insulating layers include a first insulating layer disposed between the first semiconductor pattern layer and the first conductive pattern layer, a second insulating layer disposed between the first conductive pattern layer and the second conductive pattern layer, and a third insulating layer disposed between the second conductive pattern layer and the light emitting element. The anti-shock portion is disposed in a through hole defined through at least one of the first to third insulating layers.

The first semiconductor pattern layer may include a first semiconductor pattern connected to the light emitting element, and the first conductive pattern layer may include a first gate electrode overlapping the first semiconductor pattern.

The first to third insulating layers may include an inorganic layer.

The display panel further may include a second semiconductor pattern layer disposed on the third insulating layer, a third conductive pattern layer disposed on the second semiconductor pattern layer, and a fourth conductive pattern layer disposed on the third conductive pattern layer. The insulating layers further include a fourth insulating layer disposed between the second semiconductor pattern layer and the third conductive pattern layer and a fifth insulating layer disposed between the third conductive pattern layer and the fourth conductive pattern layer, and the through hole is formed through at least one of the first to fifth insulating layers.

The first semiconductor pattern layer and the second semiconductor pattern layer may include different semiconductor materials from each other.

The through hole may be formed through the fifth insulating layer, and the anti-shock portion may be disposed on the same layer as the fourth conductive pattern layer.

The display panel further may include a shock absorption pattern disposed through at least one of the first to fifth insulating layers and including an organic material. The shock absorption pattern may have a modulus lower than the modulus of the anti-shock portion.

Embodiments of the invention provide a display panel including a base substrate including a display area, a plurality of pixels disposed on the display area, and a plurality of anti-shock portions disposed on the display area. Each of the pixels may include a pixel driving circuit and a light emitting element electrically connected to the pixel driving circuit, and each of the anti-shock portions is disposed in an area in which the pixel driving circuit is disposed and may include a metal material having a modulus equal to or greater than about 100 GPa.

The display panel further may include a shock absorption pattern disposed on the base substrate and including an organic material. The shock absorption pattern may be disposed to surround at least one pixel driving circuit among the pixel driving circuits on the display area.

According to the above, the display panel may include the anti-shock portion disposed through the portion of the circuit element layer, and the anti-shock portion may include the metal material with a relatively high modulus.

According to one or more embodiment, when an external impact is applied, the anti-shock portion reduces the stress and impacts applied to the area adjacent to the anti-shock portion. In addition, the anti-shock portion reduces a propagation of cracks caused by the external impact or the stress between the insulating layers in the circuit element layer. Accordingly, the impact resistance and the reliability of the display panel are improved.

### BRIEF DESCRIPTION OF THE DRAWINGS

The above and other advantages of the present disclosure will become readily apparent by reference to the following detailed description when considered in conjunction with the accompanying drawings where:

FIG. 1 is a perspective view of a display device according to an embodiment of the present disclosure;

FIGS. 2A and 2B are perspective views of a folded state of the display device of FIG. 1;

FIG. 3 is a cross-sectional view of a display panel according to an embodiment of the present disclosure;

FIG. 4 is a plan view of a display panel according to an embodiment of the present disclosure;

FIG. 5 is an equivalent circuit diagram of a pixel according to an embodiment of the present disclosure;

FIGS. 6A and 6B are cross-sectional views of display panels according to embodiments of the present disclosure; and

FIGS. 7A to 7G are plan views of patterns in a method of providing a pixel according to an embodiment of the present disclosure.

### DETAILED DESCRIPTION

The present disclosure may be variously modified and realized in many different forms, and thus specific embodiments will be exemplified in the drawings and described in detail hereinbelow. However, the present disclosure should not be limited to the specific disclosed forms, and be construed to include all modifications, equivalents, or replacements included in the spirit and scope of the present disclosure.

In the present disclosure, it will be understood that when an element (or area, layer, or portion) is referred to as being related to another element such as being “on”, “connected to” or “coupled to” another element or layer, it can be directly on, connected or coupled to the other element or layer or intervening elements or layers may be present. In contrast, when an element (or area, layer, or portion) is referred to as being related to another element such as being “directly on”, “directly connected to” or “directly coupled to” another element or layer, no intervening element or layer is present between the elements. Where an element is directly related to another element, such as being in contact, an interface may be formed between the elements.

Like numerals refer to like elements throughout. In the drawings, the thickness, ratio, and dimension of components are exaggerated for effective description of the technical content. Within the Figures and the text of the disclosure, a reference number indicating a singular form of an element may also be used to reference a plurality of the singular element.

The terminology used herein is for the purpose of describing particular embodiments only and is not intended to be limiting. “At least one” is not to be construed as limiting “a” or “an.” “Or” means “and/or.” As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure.

As used herein, the singular forms, “a”, “an” and “the” are intended to include the plural forms as well, unless the context clearly indicates otherwise. For example, “an element” has the same meaning as “at least one element,” unless the context clearly indicates otherwise. “At least one” is not to be construed as limiting “a” or “an.”

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a display panel DP according to an embodiment of the present disclosure will be described with reference to accompanying drawings.

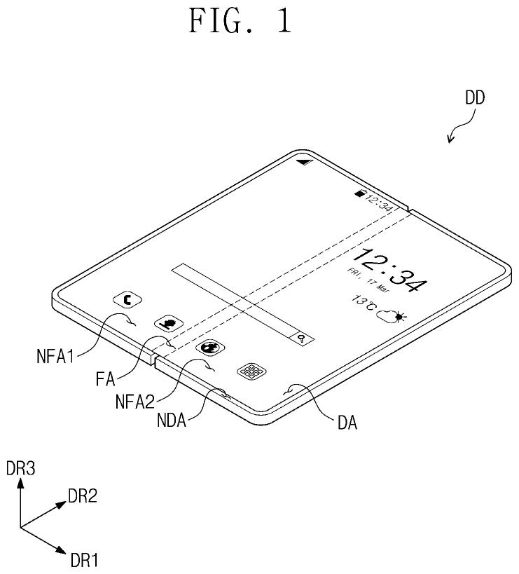

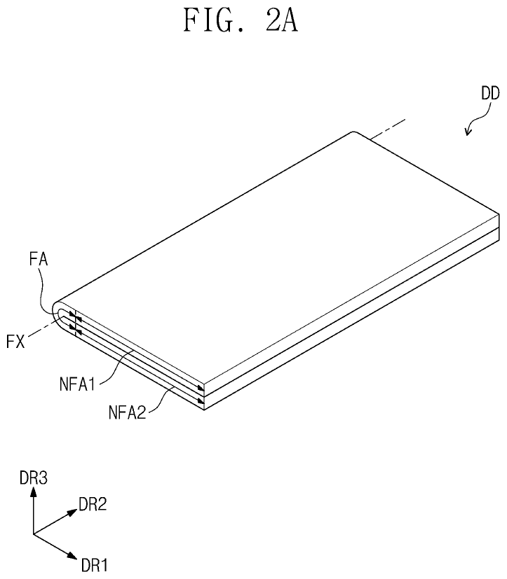

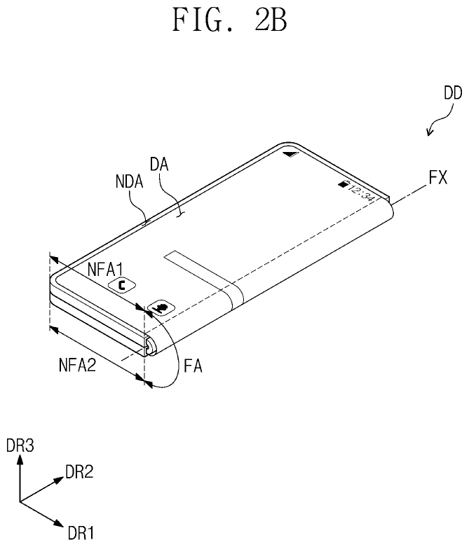

FIG. 1 is a perspective view of a display device DD according to an embodiment of the present disclosure. FIGS. 2A and 2B are perspective views of a folded state of the display device DD of FIG. 1.

The display device DD may be activated in response to electrical signals and may display an image. The display device DD may include various embodiments. As an example, the display device DD may be applied to a large-sized electronic item, such as a television set, an outdoor billboard, etc., and a small and medium-sized electronic item, such as a monitor, a mobile phone, a tablet computer, a navigation unit, a game unit, etc. However, these are merely examples, and the display device DD may be applied to other electronic items as long as they do not depart from the concept of the present disclosure. In the present embodiment, the mobile phone is shown as an example of the display device DD.

Referring to FIG. 1, the display device DD may have a rectangular shape defined by short sides extending in a first direction DR1 and long sides extending in a second direction DR2 which intersects the first direction DR1. However, the planar shape of the display device DD should not be limited to the rectangular shape, and the display device DD may have a variety of planar shapes, such as a circular shape and a polygonal shape other than the rectangular shape when viewed in a plane.

The display device DD of the present disclosure may be flexible. The term “flexible” used herein refers to the property of being able to be bent (e.g., bendable) from a structure that is completely bent to a structure that is bent at the scale of a few nanometers. For example, the flexible display device DD may be a curvable display device, a rollable display device, a slidable display device, and/or a foldable display device. In the present embodiment, the foldable display device will be described as a representative example of the flexible display device DD.

As shown in FIG. 1, when in an unfolded state, the display device DD may display the image through a display surface parallel to a plane defined by the first direction DR1 and the second direction DR2, toward a third direction DR3. The third direction DR3 may be substantially perpendicular to the plane defined by the first direction DR1 and the second direction DR2. The display surface may be a front or uppermost surface of the display device DD along the third direction DR3.

Front (or upper) and rear (or lower) surfaces of each member of the display device DD may be opposite to each other in the third direction DR3, and a normal line direction of each of the front and rear surfaces may be substantially parallel to the third direction DR3. A separation distance between the front and rear surfaces of each member (or each unit) in the third direction DR3 may correspond to a thickness of the member (or the unit) in the third direction DR3. A thickness of the display device DD and various components or layers thereof may be defined along the third direction DR3 (e.g., a thickness direction).

In the present disclosure, the expression “when viewed in a plane” or “a plan view” may mean a state of being viewed in the third direction DR3. In the present disclosure, the expression “when viewed in a cross-section” may mean a state of being viewed in the first direction DR1 or the second direction DR2. Directions indicated by the first, second, and third directions DR1, DR2, and DR3 are relative to each other, and thus, the directions indicated by the first, second, and third directions DR1, DR2, and DR3 may be changed to other directions.

The front surface of the display device DD may include a display area DA and a non-display area NDA. The display device DD may display the image through the display area DA, and a user may view the image through the display area DA since the image at the display area DA is visible from outside the display device DD. The image may include a still image as well as a video. FIG. 1 shows a clock widget and application icons as a representative example of the image.

The non-display area NDA may be an area (e.g., a planar area) where the image is not displayed. The non-display area NDA may be disposed adjacent to the display area DA. As an example, the non-display area NDA may surround the display area DA, however, this is merely an example. The non-display area NDA may be defined adjacent to only one side of the display area DA or may be defined in a side surface of the display device DD which extends bent or curved from the front surface, rather than in the front surface of the display device DD. The non-display area NDA may correspond to an area in which a printed layer with a predetermined color is formed (or provided) and may define an edge of the display device DD. A boundary may be defined between the display area DA and the non-display area NDA.

The display device DD may include a folding area FA and a non-folding area provided in plural including a plurality of non-folding areas NFA1 and NFA2. The non-folding areas NFA1 and NFA2 may include a first non-folding area NFA1 and a second non-folding area NFA2. The non-folding areas NFA1 and NFA2 may be arranged in the first direction DR1 with the folding area FA interposed therebetween.

The folding area FA may be a flat area or a curved area with a predetermined curvature depending on a folding operation. As shown in FIG. 1, when the display device DD is in the unfolded state or flat, the folding area FA may be flat. The first and second non-folding areas NFA1 and NFA2 may be flat in the folded and unfolded states. That is, the display device DD which is unfolded or flat includes the folding area FA and the non-folding area being flat.

The display device DD may be foldable such as to be folded with respect to a folding axis FX extending in one direction. Referring to FIGS. 2A and 2B, the folding axis FX may extend in the second direction DR2 substantially parallel to the long sides of the display device DD, however, should not be limited thereto or thereby. The folding axis FX may extend in a direction substantially parallel to the short sides of the display device DD. In this case, the first and second non-folding areas NFA1 and NFA2 may be arranged in the second direction DR2 with the folding area FA interposed therebetween.

The display device DD may be inwardly folded (in-folding) or outwardly folded (out-folding) with respect to the folding axis FX. The display device DD may be configured to repeat the unfolding and in-folding operations and/or to repeat the unfolding and out-folding operations. According to an embodiment, the display device DD may be configured to operate such as to display the image, in any one of the unfolding, in-folding, and out-folding operations. FIG. 2A shows the display device DD in the in-folded state, and FIG. 2B shows the display device DD in the out-folded state.

Referring to FIG. 2A, the folding axis FX may be defined to be adjacent to the front surface of the display device DD which is in-foldable. In the in-folded state, a portion of the display surface which corresponds to the folding area FA of the display device DD, may be folded to form a curved surface facing the folding axis FX. When the display device DD is in the in-folded state, a portion of the display surface which corresponds to the first non-folding area NFA1, may face a portion of the display surface which corresponds to the second non-folding area NFA2. When the display device DD is in the in-folded state, the front surface of the display device DD may not be exposed to the outside. That is, the display device DD which is in-folded includes the folding area FA having a curvature, together with portions of the non-folding area facing each other along the thickness direction of the display device DD which is folded.

Referring to FIG. 2B, the folding axis FX may be defined to be adjacent to the rear surface of the display device DD which is foldable. In the out-folded state, the display surface corresponding to the folding area FA of the display device DD may be opposite to or facing the folding axis FX and may be folded to form a curved surface. In the out-folded state, portions of the display surface respectively corresponding to the first and second non-folding areas NFA1 and NFA2 may be exposed to the outside. In the out-folded state, the portions of the display surface respectively corresponding to the first and second non-folding areas NFA1 and NFA2 may overlap each other and display the image in directions opposite to each other. In the out-folded state, the display area DA of the display device DD may be exposed to the outside and may display the image, and the user may view the image in the folded state. That is, the display device DD which is out-folded includes the folding area FA having a curvature, together with portions of the non-folding area facing away each other along the thickness direction of the display device DD which is folded.

In addition, the display device DD is inwardly folded or outwardly folded with respect to one folding axis in the present embodiment. However, the number of the folding axes defined in the display device DD should not be limited thereto or thereby, and the display device DD may be foldable with respect to a plurality of folding axes. The folding operation of the display device DD should not be limited to the above-mentioned operations and may be designed in various ways.

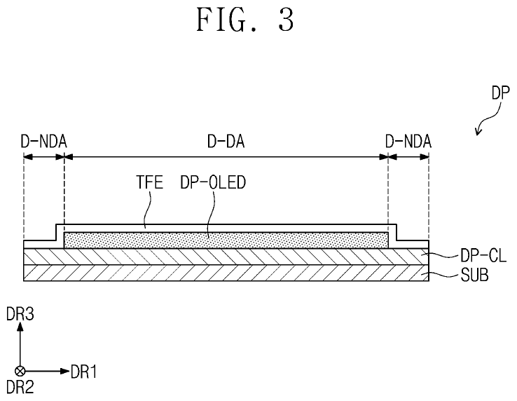

FIG. 3 is a cross-sectional view of a display panel DP according to an embodiment of the present disclosure.

The display panel DP may be included in the display device DD (refer to FIG. 1). The display panel DP may be a light emitting type display panel, however, should not be particularly limited. For example, the display panel DP may be an organic light emitting display panel, an inorganic light emitting display panel, or a quantum-dot light emitting display panel. Hereinafter, the organic light emitting display panel will be described as the display panel DP.

Referring to FIG. 3, the display panel DP may include a base substrate SUB, a circuit element layer DP-CL, a display element layer DP-OLED, and an encapsulation layer TFE.

The base substrate SUB may provide a base surface on which the circuit element layer DP-CL is disposed. The base substrate SUB may include a display area D-DA and a non-display area D-NDA. The display area D-DA and the non-display area D-NDA of the base substrate SUB may correspond to the display area DA (refer to FIG. 1) and the non-display area NDA (refer to FIG. 1) of the display device DD, respectively.

The base substrate SUB may include a flexible polymer material. As an example, the base substrate SUB may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, a perylene-based resin, and a polyimide-based resin, however, should not be limited thereto or thereby.

The circuit element layer DP-CL may be disposed on the base substrate SUB. The circuit element layer DP-CL may include at least one insulating layer, a pixel driving circuit PDC, signal lines and signal pads PD, described later. In a method of providing the display device DD, the circuit element layer DP-CL may be formed by a coating or depositing process to form an insulating layer, a semiconductor layer and a conductive layer on the base substrate SUB, and several photolithography processes to pattern the insulating layer, the semiconductor layer, and the conductive layer.

The display element layer DP-OLED may be disposed on the circuit element layer DP-CL. The display element layer DP-OLED may include light emitting elements disposed to overlap or corresponding to the display area D-DA. The light emitting elements of the display element layer DP-OLED may be electrically connected to the driving circuit of the circuit element layer DP-CL and may be driven to generate and emit a light through the display area D-DA in response to a driving signal.

The encapsulation layer TFE may be disposed on the display element layer DP-OLED and may encapsulate the light emitting elements thereof. The encapsulation layer TFE may include a plurality of thin layers. The thin layers of the encapsulation layer TFE may improve an optical efficiency of the light emitting elements or may protect the light emitting elements.

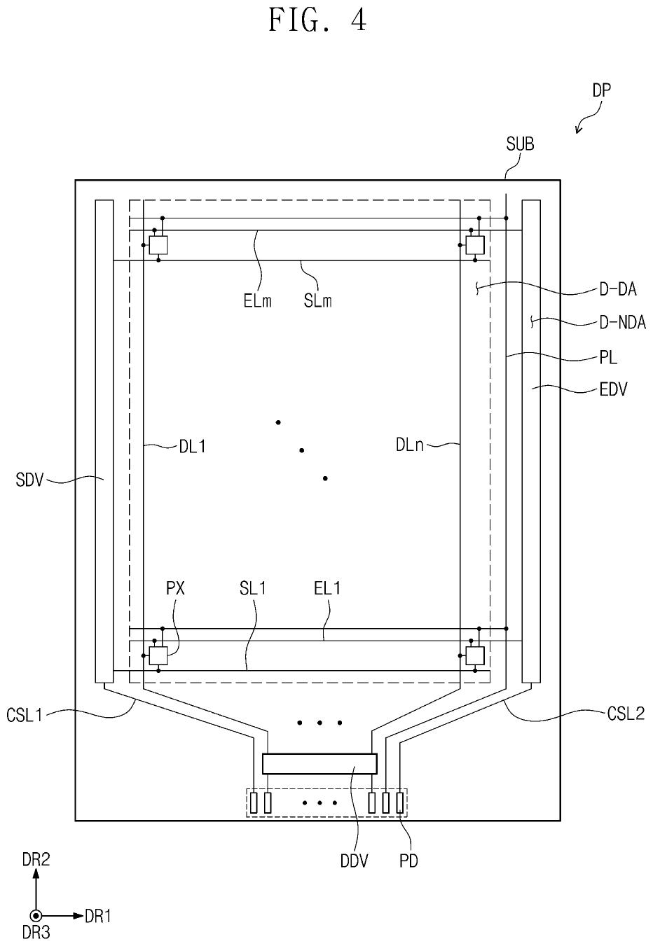

FIG. 4 is a plan view of the display panel DP according to an embodiment of the present disclosure.

Referring to FIG. 4, the display panel DP may include pixels PX disposed in the display area D-DA and signal lines which are electrically connected to the pixels PX. The display panel DP may include a scan driver SDV, a data driver DDV, an emission driver EDV, and a signal pad PD provided in plural including a plurality of signal pads PD, which are each disposed in the non-display area D-NDA.

Each of the pixels PX may include a light emitting element OLED, and a pixel driving circuit PDC including a plurality of transistors connected to the light emitting element OLED, e.g., a switching transistor, a driving transistor, etc., and at least one capacitor. Each of the pixels PX may generate and/or emit a light in response to an electrical signal applied thereto.

The signal lines may include a plurality of scan lines SL1 to SLm, a plurality of data lines DL1 to DLn, a plurality of emission lines EL1 to Elm, a first control line CSL1, a second control line CSL2, and a power line PL. Each of ‘m’ and ‘n’ is a natural number.

Each of the pixels PX may be connected to a corresponding scan line among the scan lines SL1 to SLm, a corresponding data line among the data lines DL1 to DLn, and a corresponding emission line among the emission lines EL1 to Elm. More types of signal lines may be provided in the display panel DP depending on the configuration of the pixel driving circuit PDC of the pixels PX.

The scan driver SDV and the emission driver EDV may be disposed in the non-display area D-NDA to be respectively adjacent to long sides of the display panel DP. The data driver DDV may be disposed to be adjacent to a lower end of the display panel DP when viewed in the plane.

The scan lines SL1 to SLm may extend in a direction opposite to the first direction DR1 and may be electrically connected to the scan driver SDV. The emission lines EL1 to ELm may extend in the first direction DR1 and may be connected to the emission driver EDV. The scan lines SL1 to SLm and the emission lines EL1 to ELm may be arranged in the second direction DR2. The data lines DL1 to DLn may intersect the scan lines SL1 to SLm and the emission lines EL1 to ELm when viewed in the plane. The data lines DL1 to DLn may extend in a direction opposite to the second direction DR2 and may be connected to the data driver DDV.

The power line PL may be electrically connected to the pixels PX and may provide a voltage applied to the power line PL, to the pixels PX. The power line PL may include a portion extending in the first direction DR1 and a portion extending in a direction parallel to the second direction DR2. The portion of the power line PL extending in the first direction DR1 may extend in the display area D-DA and may be connected to the pixels, and the portion of the power line PL extending in the direction parallel to the second direction DR2 may extend in the non-display area D-NDA and may be connected to the signal pads PD.

The portion of the power line PL extending in the first direction DR1 and the portion of the power line PL extending in the direction parallel to the second direction DR2 may be disposed on or in different layers from each other and may be connected to each other via a contact hole. Alternatively, the portion of the power line PL extending in the first direction DR1 and the portion of the power line PL extending in the direction parallel to the second direction DR2 may be disposed on or in the same layer as each other and may be provided integrally with each other. As being in a same layer, elements may be formed in a same process and/or include a same material as each other, elements may be respective portions of a same material layer, elements may be on a same layer by forming an interface with a same underlying or overlying layer, etc., without being limited thereto.)

The first control line CSL1 may be electrically connected to the scan driver SDV. The second control line CSL2 may be electrically connected to the emission driver EDV.

The signal pads PD may be arranged in the first direction DR1, along an edge or end portion of the display panel DP. The signal pads PD may be electrically connected to a circuit board (not shown) as a component external to the display panel DP. That is, the display panel DP may be connected to an external component, at the signal pads PD. In an embodiment, circuit board may include a timing controller to control an operation of the scan driver SDV, the data driver DDV and the emission driver EDV, and a voltage generator to generate voltages required to drive the display panel DP.

Each of the signal pads PD may be connected to a corresponding signal line among the signal lines. As an example, the first and second control lines CSL1 and CSL2, the power line PL, and the data lines DL1 to DLn may be connected to the signal pads PD. The data lines DL1 to DLn may be connected to corresponding signal pads PD via the data driver DDV.

The scan driver SDV may generate a plurality of scan signals in response to a scan control signal. The scan signals may be applied to the pixels PX via the scan lines SL1 to SLm. The data driver DDV may generate a plurality of data voltages corresponding to image signals in response to a data control signal. The data voltages may be applied to the pixels PX via the data lines DL1 to DLn. The emission driver EDV may generate a plurality of emission signals in response to an emission control signal. The emission signals may be applied to the pixels PX via the emission lines EL1 to ELm.

The pixels PX may receive the data voltages in response to the scan signals. The pixels PX may emit a light having a luminance corresponding to the data voltages in response to the emission signals, and thus, the image may be displayed. An emission time of the pixels PX may be controlled by the emission signals. Accordingly, the display panel DP may display the image through the display area D-DA using the pixels PX.

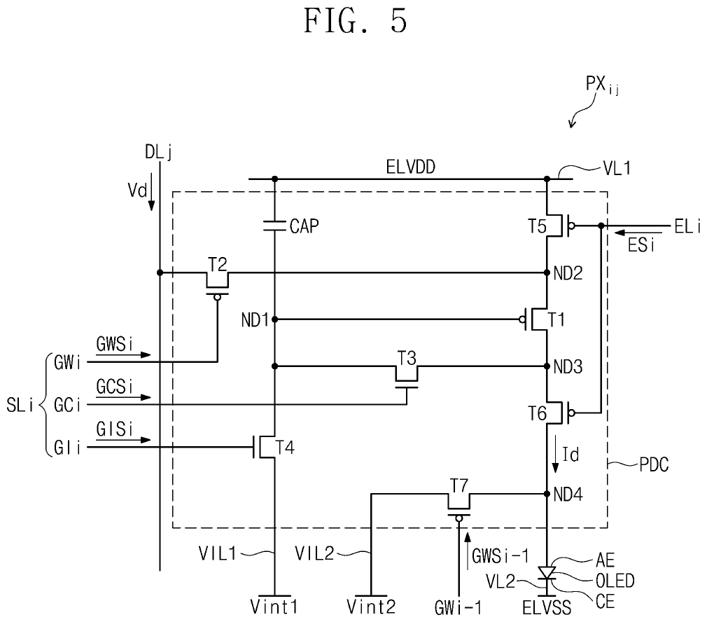

FIG. 5 is an equivalent circuit diagram of a pixel PXᵢⱼ according to an embodiment of the present disclosure. FIG. 5 shows the pixel PXᵢⱼ connected to an i-th scan line SLi, an i-th emission line ELi, and a j-th data line DLj as a representative example. In the present embodiment, ‘i’ and ‘j’ denote a natural number.

Referring to FIG. 5, the pixel PXᵢⱼ may include a light emitting element OLED and a pixel driving circuit PDC which is electrically connected to the light emitting element OLED. The pixel driving circuit PDC may include transistors T1 to T7 and a capacitor CAP. The transistors T1 to T7 and the capacitor CAP may control an amount of electrical current flowing through the light emitting element OLED, and the light emitting element OLED may generate a light with a predetermined luminance according to the amount of the current supplied thereto.

The i-th scan line SLi may include i-th first, second, and third scan lines GWi, GCi, and GIi. The first scan line GWi receiving an i-th write scan signal GWSi may be defined as a write scan line GWi. The second scan line GCi receiving an i-th compensation scan signal GCSi may be defined as a compensation scan line GCi. The third scan line GIi receiving an i-th initialization scan signal GISi may be defined as an initialization scan line GIi.

The transistors T1 to T7 may include first, second, third, fourth, fifth, sixth, and seventh transistors T1 to T7. Each of the first to seventh transistors T1 to T7 may include a plurality of electrodes or terminals including a source electrode, a drain electrode, and a gate electrode. Hereinafter, the source electrode, the drain electrode, and the gate electrode may be referred to as a source, a drain, and a gate, respectively.

In the following descriptions, the expression “a transistor is electrically connected to a signal line or another transistor.” means that a source, drain, or gate electrode of a transistor is provided integrally (e.g., directly) with a signal line or connected to a signal line through a connection electrode.

Each of the first to seventh transistors T1 to T7 may be a transistor including an oxide semiconductor layer or a transistor including a low-temperature polycrystalline silicon (LTPS) semiconductor layer. Each of the first to seventh transistors T1 to T7 may be a P-type transistor or an N-type transistor. As an example, each of the first, second, fifth, sixth, and seventh transistors T1, T2, T5, T6, and T7 may be a PMOS transistor including the LTPS semiconductor layer, and each of the third and fourth transistors T3 and T4 may be an NMOS transistor including the oxide semiconductor layer, however, the first to seventh transistors T1 to T7 should not be limited thereto or thereby. In addition, the pixel driving circuit PDC shown in FIG. 5 includes seven transistors T1 to T7, however, the number of transistors included in the pixel driving circuit PDC should not be limited thereto or thereby.

The light emitting element OLED may be defined as an organic light emitting element. The light emitting element OLED may include a first electrode AE and a second electrode CE. As an example, the first electrode AE may be an anode, and the second electrode CE may be a cathode. The first electrode AE of the light emitting element OLED may be electrically connected to a first voltage line VL1 receiving a first driving voltage ELVDD. The second electrode CE of the light emitting element OLED may be electrically connected to a second voltage line VL2 receiving a second driving voltage ELVSS.

The first transistor T1 may be electrically connected between the first voltage line VL1 receiving the first driving voltage ELVDD and the light emitting element OLED. The first transistor T1 may include the source connected to a second node ND2, the drain connected to a third node ND3, and the gate connected to a first node ND1. The first transistor T1 may be turned on in response to a voltage at the first node ND1. The first transistor T1 may receive a data voltage Vd transmitted by the data line DLj in response to a switching operation of the second transistor T2 and may supply a driving current Id to the light emitting element OLED. In the present embodiment, the first transistor T1 may be defined as a driving transistor.

The second transistor T2 may be electrically connected between the data line DLj and the first transistor T1. The second transistor T2 may include the source connected to the data line DLj, the drain connected to the second node ND2, and the gate connected to the first scan line GWi. The second transistor T2 and the first transistor T1 may be connected to each other at the second node ND2. The second transistor T2 may be turned on in response to the write scan signal GWSi applied thereto via the first scan line GWi. The data voltage Vd applied to the data line DLj via the turned-on second transistor T2 may be transmitted to the source of the first transistor T1. In the present embodiment, the second transistor T2 may be defined as a switching transistor.

The third transistor T3 may be electrically connected between the fourth transistor T4 and the first transistor T1. The third transistor T3 may include the source connected to the first node ND1, the drain connected to the third node ND3, and the gate connected to the second scan line GCi. The third transistor T3 and the first transistor T1 may be connected to each other at the third node ND3. The third transistor T3 may be turned on in response to the compensation scan signal GCSi applied thereto via the second scan line GCi. The gate of the first transistor T1 may be electrically connected to the drain of the first transistor T1 by the turned-on third transistor T3, and the first transistor T1 may be connected in a diode configuration. In the present embodiment, the third transistor T3 may be defined as a compensation transistor.

The fourth transistor T4 may be electrically connected between a first initialization voltage line VIL1 to which a first initialization voltage Vint1 is applied and the third transistor T3. The fourth transistor T4 may include the source connected to the first initialization voltage line VIL1, the drain connected to the first node ND1, and the gate connected to the third scan line GIi. The fourth transistor T4 may be turned on in response to the initialization scan signal GISi applied thereto via the third scan line GIi. The turned-on fourth transistor T4 may transmit the first initialization voltage Vint1 to the first node ND1 to initialize an electric potential of the gate of the first transistor T1. In the present embodiment, the fourth transistor T4 may be defined as an initialization transistor.

The fifth transistor T5 may be electrically connected between the first voltage line VL1 receiving the first driving voltage ELVDD and the first transistor T1. The fifth transistor T5 may include the source connected to the first voltage line VL1, the drain connected to the second node ND2, and the gate connected to the emission line ELi.

The sixth transistor T6 may be electrically connected between the first transistor T1 and the light emitting element OLED. The sixth transistor T6 may include the source connected to the third node ND3, the drain connected to the first electrode AE of the light emitting element OLED via a fourth node ND4, and the gate connected to the emission line ELi.

The fifth transistor T5 and the sixth transistor T6 may be turned on in response to the emission signal ESi applied thereto via the emission line ELi. An emission time of the light emitting element OLED may be controlled by the emission signal ESi. When the fifth transistor T5 and the sixth transistor T6 are turned on, the driving current Id may be generated according to a voltage difference between a gate voltage of the gate of the first transistor T1 and the first driving voltage ELVDD, the driving current Id may be supplied to the light emitting element OLED via the sixth transistor T6, and thus, the light emitting element OLED may emit the light. In the present embodiment, each of the fifth transistor T5 and the sixth transistor T6 may be defined as a light emission control transistor.

The seventh transistor T7 may be electrically connected between the sixth transistor T6 and a second initialization line VIL2 to which a second initialization voltage Vint2 is applied. The seventh transistor T7 may include the source connected to the fourth node ND4, the drain connected to the second initialization line VIL2, and the gate connected to the first scan line GWi−1. The gate of the seventh transistor T7 may be connected to an (i−1)th write scan line GWi−1 that is a previous write scan line of the i-th write scan line GWi, however, should not be limited thereto or thereby. According to an embodiment, the gate of the seventh transistor T7 may be electrically connected to a separate fourth scan line (not shown).

The seventh transistor T7 may be turned on in response to an (i−1)th write scan signal GWSi−1 applied thereto via the first scan line GWi−1. The turned on seventh transistor T7 may transmit the second initialization voltage Vint2 to the fourth node ND4. The second initialization voltage Vint2 may have the same level as the first initialization voltage Vint1, however, should not be limited thereto or thereby. According to an embodiment, the second initialization voltage Vint2 may have a level different from that of the first initialization voltage Vint1. In the present embodiment, the seventh transistor T7 may be defined as an initialization transistor.

The seventh transistor T7 may improve the ability to display deep black color of the pixel PXᵢⱼ. A portion of the driving current Id may be bypassed as a bypass current via the seventh transistor T7. In a case where a black image is displayed, a current reduced by an amount of the bypass current, which is bypassed through the seventh transistor T7, from the driving current Id may be provided to the light emitting element OLED, and thus, the black image may be clearly displayed. That is, the pixel PX may display an accurate black luminance image using the seventh transistor T7, and as a result, a contrast ratio of the display device DD (refer to FIG. 1) may be improved.

The capacitor CAP may include a first electrode receiving the first driving voltage ELVDD and a second electrode connected to the first node ND1. The capacitor CAP may be charged with electric charges corresponding to a difference in voltage between the first electrode and the second electrode. When the fifth transistor T5 and the sixth transistor T6 are turned on, the amount of electrical current flowing through the first transistor T1 may be determined according to the voltage charged in the capacitor CAP.

The configuration of the pixel driving circuit PDC shown in FIG. 5 is merely an example, and the configuration of the pixel driving circuit PDC may be changed without being limited to the embodiment shown in FIG. 5.

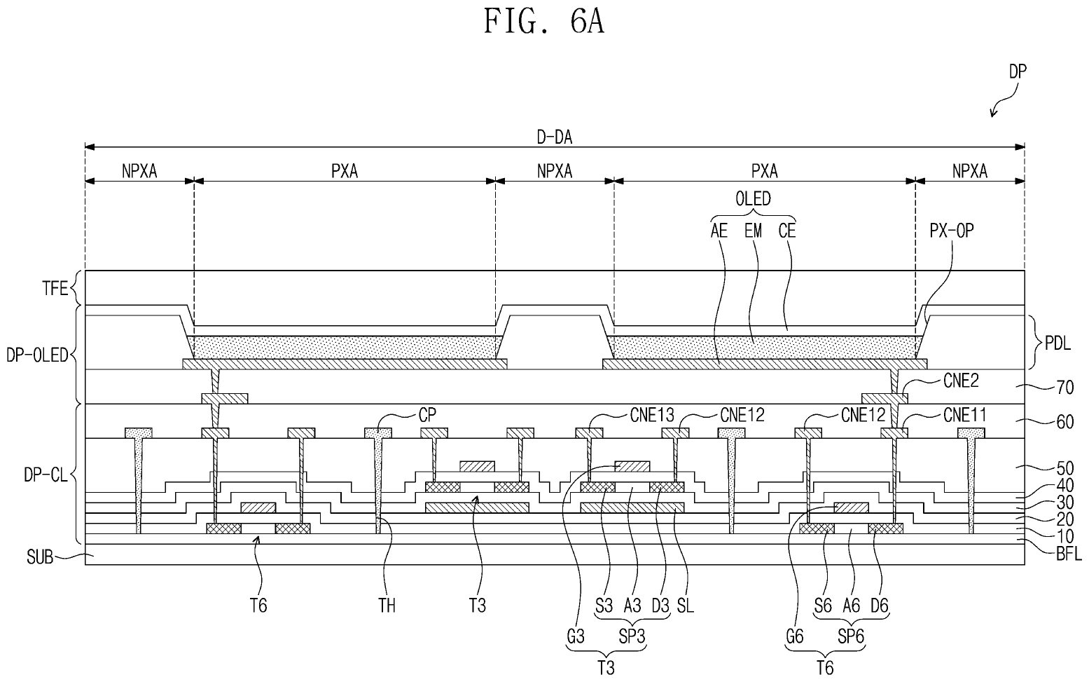

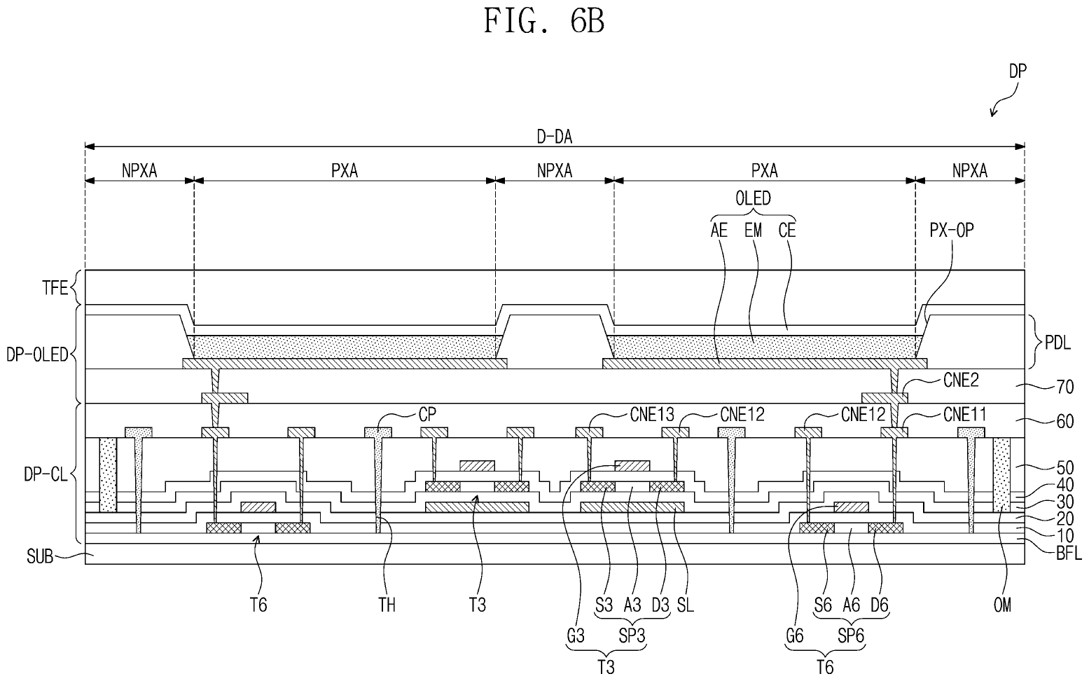

FIGS. 6A and 6B are cross-sectional views of respective display panels DP according to embodiments of the present disclosure. FIGS. 6A and 6B show the light emitting elements OLED and some transistors T3 and T6 of the pixel driving circuits PDC (refer to FIG. 5), which are respectively connected to the light emitting elements OLED, as a representative example. Details of the components of the display panel DP described above may be applied to those of the display panel DP shown in FIGS. 6A and 6B.

Referring to FIGS. 6A and 6B, the display panel DP may include the base substrate SUB, the circuit element layer DP-CL, the display element layer DP-OLED, and the encapsulation layer TFE.

The base substrate SUB may provide a base surface on which the circuit element layer DP-CL is disposed. The circuit element layer DP-CL may include insulating layers BFL and 10 to 70, the transistors T3 and T6 in a transistor layer, connection electrodes CNE11 to CNE13 and CNE2 in a connection electrode layer, and an anti-shock portion CP as an anti-shock pattern of an anti-shock layer.

The insulating layers BFL and 10 to 70 may include a buffer layer BFL and first, second, third, fourth, fifth, sixth, and seventh insulating layers 10, 20, 30, 40, 50, 60, and 70 which are disposed on the buffer layer BFL. However, the insulating layers included in the circuit element layer DP-CL should not be limited thereto or thereby and may be changed depending on components of the pixel driving circuit PDC included in the circuit element layer DP-CL and processes for providing (or forming) the circuit element layer DP-CL. More than one of the insulating layers BFL and 10 to 70 may be referred to as an insulating layer.

The buffer layer BFL may be disposed on the base substrate SUB. The buffer layer BFL may include at least one inorganic layer. As an example, the buffer layer BFL may include at least one of aluminum oxide, titanium oxide, silicon oxide, silicon nitride, silicon oxynitride, zirconium oxide, and hafnium oxide. The buffer layer BFL may improve an adhesive force between and the base substrate SUB and a semiconductor pattern layer of the circuit element layer DP-CL which is disposed on the base substrate SUB, e.g., a sixth semiconductor pattern SP6, or a conductive pattern layer.

Each of the first to seventh insulating layers 10 to 70 may include an inorganic layer and/or an organic layer and may have a single-layer or multi-layer structure. The inorganic layer may include at least one of aluminum oxide, titanium oxide, silicon oxide, silicon nitride, silicon oxynitride, zirconium oxide, and hafnium oxide, however, a material for the inorganic layer should not be limited thereto or thereby. The organic layer may include at least one of an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin. However, a material for the organic layer should not be limited thereto or thereby.

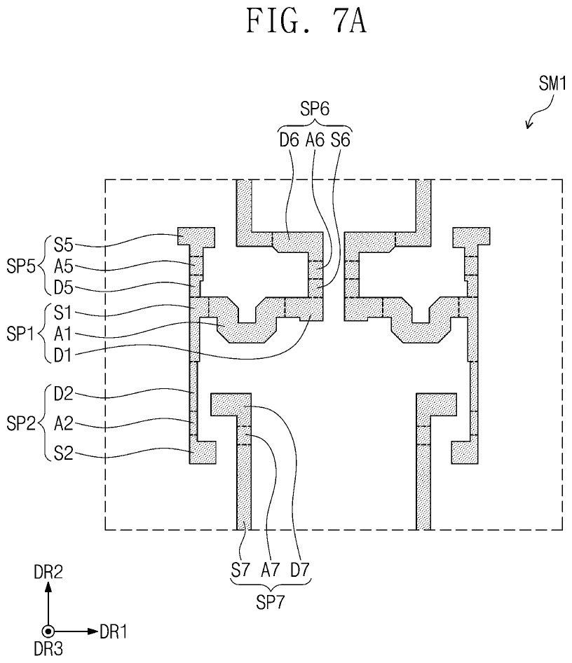

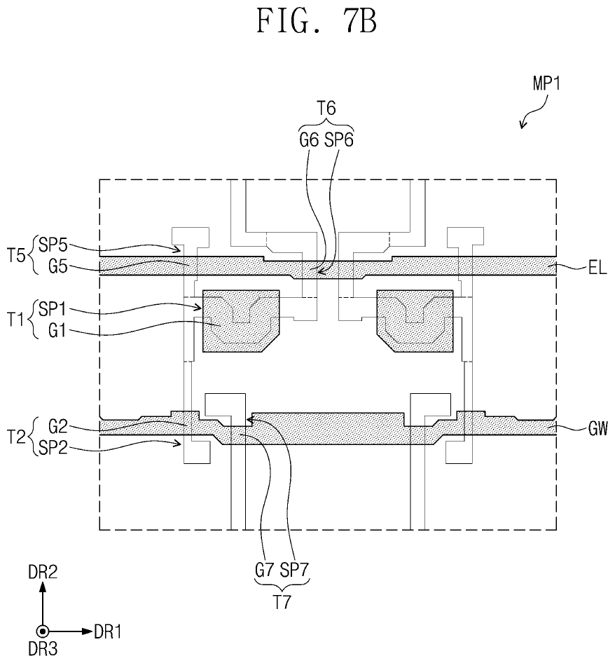

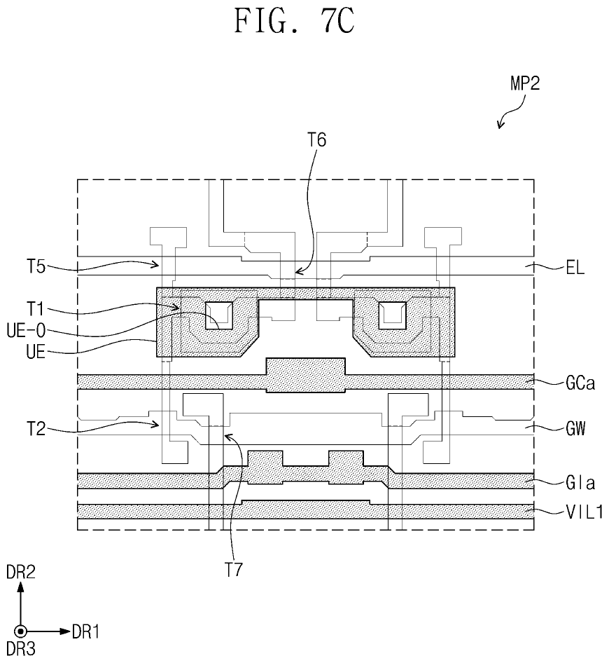

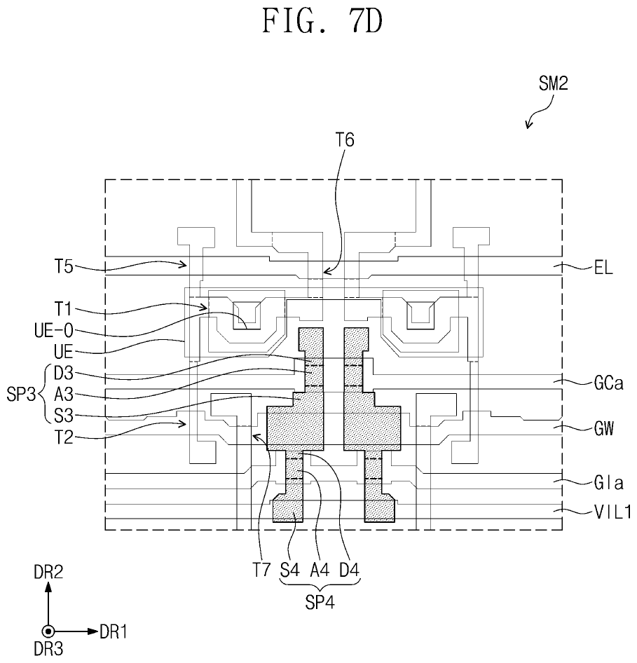

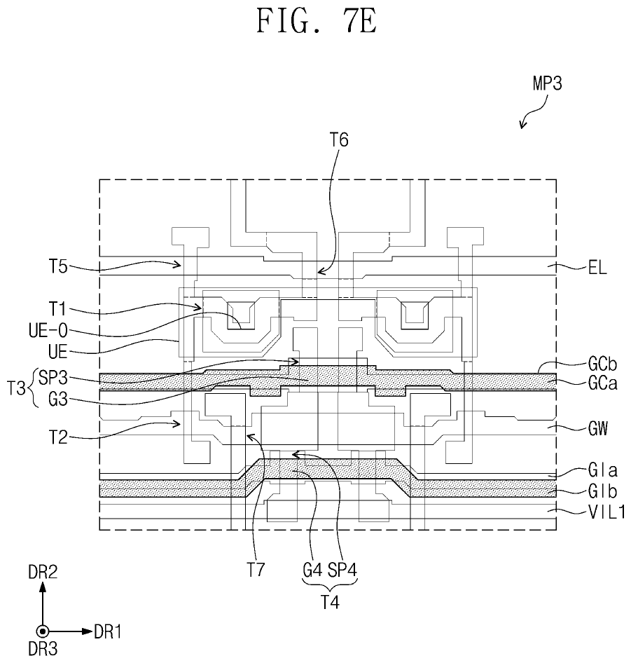

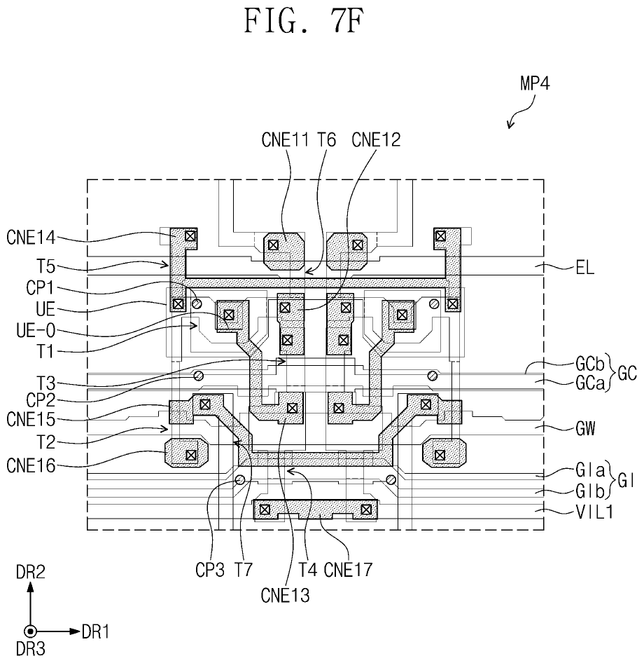

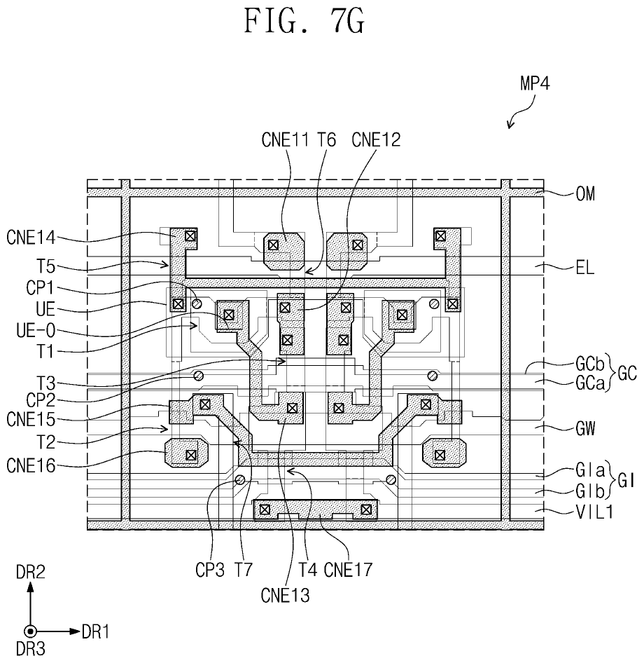

A first semiconductor pattern layer SM1 (refer to FIG. 7A) may be disposed on the base substrate SUB. As an example, the first semiconductor pattern layer SM1 may be disposed on the buffer layer BFL. The first semiconductor pattern layer SM1 may include a silicon semiconductor. As an example, the first semiconductor pattern layer SM1 may include polysilicon or amorphous silicon. However, the first semiconductor patterns should not be limited thereto or thereby as long as the first semiconductor pattern layer SM1 has a semiconductor property.

The first semiconductor pattern layer SM1 may include plural regions having different electrical properties from each other, depending on whether a respective region is doped or not, or whether the respective region is doped with an N-type dopant or a P-type dopant. The first semiconductor pattern layer SM1 may include a first region having a high conductivity and a second region having a low conductivity. The first region may be doped with the N-type dopant or the P-type dopant. A P-type transistor may include a doped region doped with the P-type dopant, and an N-type transistor may include a doped region doped with the N-type dopant. The second region may be a non-doped region or a region doped with a relatively low concentration compared with the first region.

The first region may have the conductivity greater than that of the second region and may substantially serve as a source and a drain of a transistor. The second region may substantially correspond to a channel (or an active) of the transistor. In other words, the first region of the first semiconductor pattern layer SM1 which has the relatively high conductivity may be the source or drain of the transistor or a connection signal line, and the second region of the first semiconductor pattern layer which has the relatively low conductivity may be the channel of the transistor.

Referring to FIGS. 6A and 6B, the sixth semiconductor pattern SP6 of the sixth transistor T6 may be formed (or provided) from the first semiconductor pattern layer SM1. The sixth semiconductor pattern SP6 may include a sixth source S6, a sixth channel A6, and a sixth drain D6. The sixth source S6 and the sixth drain D6 may extend in opposite directions to each other, from the sixth channel A6. That is, the sixth source S6 and the sixth drain D6 may be spaced apart from each other with the sixth channel A6 interposed therebetween. Within the semiconductor pattern, the sixth channel A6 may connect the sixth source S6 and the sixth drain D6 to each other.

The first insulating layer 10 may be disposed on the buffer layer BFL. The first insulating layer 10 may cover the first semiconductor pattern layer SM1. As an example, the first insulating layer 10 may cover the sixth semiconductor pattern SP6.

A first conductive pattern layer MP1 may be disposed on the first insulating layer 10. A sixth gate electrode G6 may be formed from the first conductive pattern layer MP1 and may be disposed on the first insulating layer 10. The sixth gate electrode G6 may overlap the sixth channel A6. According to an embodiment of a method of providing the display panel DP, the sixth gate electrode G6 may serve as a mask in a process of doping the sixth semiconductor pattern SP6.

FIGS. 6A and 6B show a top-gate structure in which the sixth transistor T6 includes the sixth gate electrode G6 disposed on the sixth semiconductor pattern SP6 to be further from the base substrate SUB than the respective semiconductor pattern, as a representative example, however, the present disclosure should not be limited thereto or thereby. According to an embodiment, the sixth transistor T6 may have a bottom-gate structure in which the sixth gate electrode G6 is disposed under the sixth semiconductor pattern SP6 (e.g., closer to the base substrate SUB than the respective semiconductor pattern).

The first, second, fifth, and seventh transistors T1, T2, T5, and T7 (refer to FIG. 5) may have the same structure as the sixth transistor T6. As an example, semiconductor patterns of the first, second, fifth, and seventh transistors T1, T2, T5, and T7 (refer to FIG. 5) may be formed from the first semiconductor pattern layer SM1 in the same way as the sixth semiconductor pattern SP6, and gate electrodes of the first, second, fifth, and seventh transistors T1, T2, T5, and T7 (refer to FIG. 5) may be formed from the first conductive pattern layer SM1 in the same way and/or at the same time as the sixth gate electrode G6, however, the present disclosure should not be limited thereto or thereby.

The second insulating layer 20 may be disposed on the first insulating layer 10. The second insulating layer 20 may cover the first conductive pattern layer MP1. As an example, the second insulating layer 20 may cover the sixth gate electrode G6.

A second conductive pattern layer MP2 may be disposed on the second insulating layer 20. The second conductive pattern layer MP2 may include a scan line SL. Although not shown in FIGS. 6A and 6B, the second conductive pattern layer MP2 may further include an upper electrode UE (refer to FIG. 7C). The scan line SL may correspond to or define portions of the first, second, and third scan lines GWi, GCi, and GIi (refer to FIG. 5).

The third insulating layer 30 may be disposed on the second insulating layer 20. The third insulating layer 30 may cover the second conductive pattern layer MP2. As an example, the third insulating layer 30 may cover the scan line SL.

A second semiconductor pattern layer SM2 (refer to FIG. 7D) may be disposed on the third insulating layer 30. The second semiconductor pattern layer SM2 (refer to FIG. 7D) may include a semiconductor material different from that of the first semiconductor pattern layer SM1. As an example, the second semiconductor pattern layer SM2 may include an oxide semiconductor including metal oxide. As an example, the oxide semiconductor may include the metal oxide of metals, such as zinc (Zn), indium (In), gallium (Ga), tin (Sn), titanium (Ti), etc., or a mixture of the metals, such as zinc (Zn), indium (In), gallium (Ga), tin (Sn), titanium (Ti), etc., and oxides thereof. The oxide semiconductor may include indium-tin oxide (ITO), indium-gallium-zinc oxide (IGZO), zinc oxide (ZnO), indium-zinc oxide (IZO), zinc-indium oxide (ZIO), indium oxide (InO), titanium oxide (TiO), indium-zinc-tin oxide (IZTO), zinc-tin oxide (ZTO), or the like. However, the present disclosure should not be limited thereto or thereby.

The second semiconductor pattern layer SM2 may include a plurality of areas (e.g. planar areas) having different electrical properties from each other, depending on whether the metal oxide at a respective planar area is reduced or not. An area (hereinafter, referred to as a reduced area) where the metal oxide is reduced may have a conductivity higher than that of an area (hereinafter, referred to as a non-reduced area) where the metal oxide is not reduced. The reduced area may substantially act as the source or the drain of the transistor. The non-reduced area may substantially correspond to the channel (or the active) of the transistor.

Referring to FIGS. 6A and 6B, a third semiconductor pattern SP3 of the third transistor T3 may be formed from the second semiconductor pattern layer SM2. The third semiconductor pattern SP3 may include a third source S3, a third channel A3, and a third drain D3. The third source S3 and the third drain D3 may extend in opposite directions to each other from the third channel A3. That is, the third source S3 and the third drain D3 may be spaced apart from each other with the third channel A3 interposed therebetween when viewed in the plane.

The fourth insulating layer 40 may be disposed on the third insulating layer 30. The fourth insulating layer 40 may cover the second semiconductor pattern layer SM2. As an example, the fourth insulating layer 40 may cover the third semiconductor pattern SP3.

A third conductive pattern layer MP3 may be disposed on the fourth insulating layer 40. A third gate electrode G3 may be formed from the third conductive pattern layer MP3 and may be disposed on the fourth insulating layer 40. The third gate electrode G3 may overlap the third channel A3. According to an embodiment, the third gate electrode G3 may serve as a mask in a process of doping the third semiconductor pattern SP3.

The third semiconductor pattern SP3 may overlap a portion of the scan line SL which is disposed under the third semiconductor pattern SP3. The portion of the scan line SL, which overlaps the third semiconductor pattern SP3, may act as the gate of the third transistor T3 together with the third gate electrode G3. In this case, a third gate of the third transistor T3 may be formed in a double-layer structure, and thus, the third gate of the third transistor T3 may have a sufficient amount of gate charge and may be switched at high speed. In addition, as the scan line SL is disposed to overlap the third semiconductor pattern SP3, damage caused to the third semiconductor pattern SP3 by a light traveling to the display panel DP from a lower side of the display panel DP may be prevented. That is, since light is incident to the scan line SL under the third semiconductor pattern SP3, before being incident to the third semiconductor pattern SP3, damage to the third semiconductor pattern SP3 by the light, may be reduced or effectively prevented. However, this structure of the third transistor T3 is merely an example, and the present disclosure should not be limited thereto or thereby.

The fourth transistor T4 (refer to FIG. 5) may have the same structure as the third transistor T3. As an example, a semiconductor pattern of the fourth transistor T4 (refer to FIG. 5) may be formed from the second semiconductor pattern SM2 layer in the same way as the third semiconductor pattern SP3, and the gate electrode of the fourth transistor T4 (refer to FIG. 5) may be formed from the third conductive pattern MP3 layer in the same way as the third gate electrode G3. However, the present disclosure should not be limited thereto or thereby.

The third semiconductor pattern SP3 of the third transistor T3 and the sixth semiconductor pattern SP6 of the sixth transistor T6 may be disposed on different layers from each other, however, the present disclosure should not be limited thereto or thereby. According to an embodiment, the semiconductor patterns of all transistors included in the pixel driving circuit PDC (refer to FIG. 5) may be disposed on the same layer.

The fifth insulating layer 50 may be disposed on the fourth insulating layer 40. The fifth insulating layer 50 may cover the third conductive pattern layer MP3. As an example, the fifth insulating layer 50 may cover the third gate electrode G3.

A fourth conductive pattern layer MP4 may be disposed on the fifth insulating layer 50. The connection electrodes CNE11 to CNE13 may be formed from the fourth conductive pattern layer MP4. The connection electrodes CNE11 to CNE13 may include first-first, first-second, and first-third connection electrodes CNE11, CNE12, and CNE13. The first-first to first-third connection electrodes CNE11 to CNE13 may be disposed spaced apart from each other in a direction along the circuit element layer DP-CL, on the same layer, for example, the fifth insulating layer 50. That is, the first-first to first-third connection electrodes CNE11 to CNE13 are respective patterns of a first connection electrode layer defined by the fourth conductive pattern layer MP4.

The first-first connection electrode CNE11 may be connected to the sixth drain D6 of the sixth transistor T6. The first-first connection electrode CNE11 may be connected to the sixth drain D6 via a contact hole defined through the first to fifth insulating layers 10 to 50.

The first-second connection electrode CNE12 may be connected to the sixth source S6 of the sixth transistor T6. The first-second connection electrode CNE12 may be connected to the sixth source S6 via a contact hole defined through the first to fifth insulating layers 10 to 50.

When viewed in the plane, the first-second connection electrode CNE12 may extend from the sixth transistor T6 to overlap the third drain D3 of the third transistor T3. The first-second connection electrode CNE12 may be connected to the third drain D3 via a contact hole defined through the fourth and fifth insulating layers 40 and 50. Accordingly, the third semiconductor pattern SP3 of the third transistor T3 and the sixth semiconductor pattern SP6 of the sixth transistor T6, which are disposed on different layers from each other, may be electrically connected to each other by the first-second connection electrode CNE12. That is, a same connection electrode (e.g., the first-second connection electrode CNE12) connects the third transistor T3 to the sixth transistor T6.

The first-third connection electrode CNE13 may be connected to the third source S3 of the third transistor T3. The first-third connection electrode CNE13 may be connected to the third source S3 via a contact hole defined through the fourth and fifth insulating layers 40 and 50.

The sixth insulating layer 60 may be disposed on the fifth insulating layer 50. The sixth insulating layer 60 may cover the fourth conductive pattern layer MP4. As an example, the sixth insulating layer 60 may cover the first-first to first-third connection electrodes CNE11 to CNE13.

A fifth conductive pattern layer may be disposed on the sixth insulating layer 60. A second connection electrode CNE2 may be formed from the fifth conductive pattern layer. In addition, although not shown in figures, some of the signal lines included in the display panel DP may be formed from the fifth conductive pattern layer. The second connection electrode CNE2 may be provided in plural as second connection electrodes which are respective patterns of a second connection electrode layer defined by the fifth conductive pattern layer.

The second connection electrode CNE2 may be connected to the first-first connection electrode CNE11 via a contact hole defined through the sixth insulating layer 60. The second connection electrode CNE2 may be connected to the sixth drain D6 of the sixth transistor T6 by the first-first connection electrode CNE11, however, the present disclosure should not be limited thereto or thereby. According to an embodiment, the second connection electrode CNE2 may be omitted, or the circuit element layer DP-CL may further include an additional connection electrode disposed between the second connection electrode CNE2 and the first-first connection electrode CNE11.

The seventh insulating layer 70 may be disposed on the sixth insulating layer 60. The seventh insulating layer 70 may cover the fifth conductive pattern layer. As an example, the seventh insulating layer 70 may cover the second connection electrode CNE2.

At least one of the sixth insulating layer 60 and the seventh insulating layer 70 may include an organic layer. The organic layer may cover particles existing on a surface of layers disposed thereunder or a step difference between components disposed thereunder to provide a flat surface. In addition, the organic layer may relieve a stress between components disposed thereon and components disposed thereunder.

The display panel DP may include the anti-shock portion CP disposed inside the circuit element layer DP-CL. The anti-shock portion CP may be disposed in an area where the pixel driving circuit PDC (refer to FIG. 5) is disposed. The anti-shock portion CP may be provided in plural in the area where one pixel driving circuit PDC (refer to FIG. 5) is disposed, or one anti-shock portion CP may be provided in the area where one pixel driving circuit PDC (refer to FIG. 5) is disposed.

The anti-shock portion CP may be formed by forming a first through hole TH having a predetermined depth in a thickness direction of the display panel DP through a portion of the circuit element layer DP-CL and filling a material with a relatively high modulus in the first through hole TH. Accordingly, the size of the modulus of the material filled in the first through hole TH may affect the extent to which the anti-shock portion CP relieves stress within the display panel DP.

The anti-shock portion CP may be disposed in the first through hole TH penetrating at least some of the insulating layers 10 to 70 included in the circuit element layer DP-CL. FIGS. 6A and 6B show the anti-shock portion CP disposed in the first through hole TH penetrating the first to fifth insulating layers 10 to 50 as a representative example. However, the depth of the first through hole TH in which the anti-shock portion CP is disposed and the thickness of the anti-shock portion CP may be changed depending on the structure of the circuit element layer DP-CL overlapping the anti-shock portion CP and/or process conditions to form the first through hole TH and should not be particularly limited.

The anti-shock portion CP may include a material with a relatively high modulus. As an example, the anti-shock portion CP may include a metal material having a modulus of about 100 gigapascals (GPa) or more. For instance, the anti-shock portion CP may include molybdenum (Mo), titanium (Ti), or alloys thereof. The anti-shock portion CP may have a single-layer structure of a metal layer or a multi-layer structure of a plurality of metal layers stacked in the thickness direction of the display panel DP. However, the material and structure of the anti-shock portion CP should not be particularly limited as long as the anti-shock portion CP has the modulus of about 100 GPa or more.

The anti-shock portion CP may be disposed on the same layer as the fourth conductive pattern layer MP4. As an example, the anti-shock portion CP and the first-first to first-third connection electrodes CNE11 to CNE13 may be disposed on the same fifth insulating layer 50. In a method of providing the display panel DP, the first through hole TH in which the anti-shock portion CP is disposed may be substantially simultaneously formed or provided with the contact holes overlapping the first-first to first-third connection electrodes CNE11 to CNE13. Accordingly, separate processes required to form the first through hole TH may be omitted, however, the present disclosure should not be limited thereto or thereby. According to an embodiment, the first through hole TH may be formed through a process separately from the process of forming the contact hole.

In a method of providing the display panel DP, the anti-shock portion CP as an anti-shock pattern may be simultaneously formed with other conductive patterns of the fourth conductive pattern layer MP4. As an example, the anti-shock portion CP may be formed through the same processes as the first-first to first-third connection electrodes CNE11 to CNE13. The anti-shock portion CP may include the same material as the first-first to first-third connection electrodes CNE11 to CNE13. As an example, the anti-shock portion CP and the first-first to first-third connection electrodes CNE11 to CNE13 may have a three-layer structure of conductive layers, e.g., Ti/Al/Ti. However, materials for the anti-shock portion CP and the first-first to first-third connection electrodes CNE11 to CNE13 should not be limited thereto or thereby. As the anti-shock portion CP is formed through the same process as the connection electrodes CNE11 to CNE13, separate processes or separate masks, which are required to form the anti-shock portion CP, may be omitted. As a result, a material and a process cost, which are required to form the anti-shock portion CP, may be reduced.

However, the present disclosure should not be limited thereto or thereby. Even though the anti-shock portion CP is disposed on the same layer as the first-first to first-third connection electrodes CNE11 to CNE13, the anti-shock portion CP may be formed through separate processes from the first connection electrodes. In this case, the anti-shock portion CP may not be formed of or include the same material as the first-first to first-third connection electrodes CNE11 to CNE13, and the anti-shock portion CP may be designed to have a modulus necessary for an impact resistance required for the display panel DP without material restrictions.

The anti-shock portion CP may be disposed in an area where the stress relief is required inside the circuit element layer DP-CL without affecting the driving of the pixel including elements within or at the stress-relief area. As an example, the anti-shock portion CP may be disposed adjacent to the transistors T3 and T6 but may not overlap the elements including the sources S3 and S6 and the drains D3 and D6 of the transistors T3 and T6. Accordingly, the anti-shock portion CP may relieve the stress applied to the area adjacent to the transistors T3 and T6 without affecting the driving of the transistors T3 and T6. As not overlapping, elements may be adjacent to or spaced apart from each other in a planar direction, such as along the plane defined by the first direction DR1 and the second direction DR2 crossing each other.

When some transistors of the pixel driving circuit PDC are damaged, defects such as a bright spot or a dark spot may occur on the display panel DP. As an example, when the second transistor T2 (refer to FIG. 5) or the third transistor T3 is damaged, the light emitting element OLED may continuously emit the light, and thus, the defect such as the bright spot may occur. When the fifth transistor T5 (refer to FIG. 5) or the sixth transistor T6 is damaged, the light emitting element OLED may not emit the light, and thus, the defect such as the dark spot may occur. The anti-shock portion CP may be disposed in an area adjacent to the transistors without disconnecting or short-circuiting the pixel driving circuit to reduce the defects of the display panel DP, and thus, damages to the transistors due to external impacts and stress may be prevented.

In addition, the anti-shock portion CP may reduce a propagation of cracks between the insulating layers 10 to 50, especially between inorganic layers, due to the stress caused by external impacts or folding operations. Referring to FIGS. 6A and 6B, for example, the anti-shock portion CP extends between the uppermost insulating layer (e.g., the sixth insulating layer 60) and the lowermost insulating layer (e.g., the buffer layer BFL) within the circuit element layer DP-CL. Accordingly, the display panel DP may have a strong structure, which is not easily damaged by external impacts or the stress due to folding operations, by the anti-shock portion CP, and thus, the reliability of the display panel DP may be improved.

Referring to FIG. 6B, the display panel DP may further include a shock absorption pattern OM disposed in the circuit element layer DP-CL. The shock absorption pattern OM may be disposed to surround the elements of at least one pixel driving circuit PDC (refer to FIG. 5) when viewed in the plane. FIG. 6B shows a cross-section of the shock absorption pattern OM disposed to surround two pixel driving circuits PDC (refer to FIG. 5) adjacent to each other when viewed in the plane.

The shock absorption pattern OM may be formed by filling a material with a relatively low modulus in a second through hole formed through at least one of the insulating layers 10 to 70 of the circuit element layer DP-CL. FIG. 6B shows the shock absorption pattern OM disposed in the through hole defined penetrating completely through the third to fifth insulating layers 30 to 50 as a representative example. However, a thickness of the shock absorption pattern OM should not be particularly limited in the thickness direction of the display panel DP. As an example, the shock absorption pattern OM may be formed extended completely through the first to fifth insulating layers 10 to 50. The thickness of the shock absorption pattern OM may vary depending on the structure of the circuit element layer DP-CL overlapping the shock absorption pattern OM or process conditions to form the shock absorption pattern OM, and should not be particularly limited.

The shock absorption pattern OM may include a material having a relatively low modulus. The modulus of the shock absorption pattern OM may be lower than the modulus of the anti-shock portion CP. As an example, the shock absorption pattern OM may include an organic material. The shock absorption pattern OM may have the modulus lower than that of the respective insulating layer of the circuit element layer DP-CL through which the shock absorption pattern OM penetrates, however, the present disclosure should not be limited thereto or thereby.

As the shock absorption pattern OM is disposed to surround a specific planar area in the circuit element layer DP-CL, the shock absorption pattern OM may absorb external impacts applied to the planar area and the circuit elements surrounded thereby, and may reduce the external impacts transmitted to other areas other than the planar area. The shock absorption pattern OM may improve an anti-impact resistance of the display panel DP together with the anti-shock portion CP. The shock absorption pattern OM as a first shock absorption pattern together with the anti-shock portion CP as a second shock absorption pattern may provide a shock absorption pattern layer within the circuit element layer DP-CL.

Referring to FIGS. 6A and 6B, the display element layer DP-OLED may be disposed on the circuit element layer DP-CL. The display element layer DP-OLED may include a pixel definition layer PDL and the light emitting elements OLED. Each of the light emitting elements OLED may include the first electrode AE, a light emitting layer EM, and the second electrode CE.

The light emitting elements OLED may include an organic light emitting element, a quantum dot light emitting element, a micro-light emitting diode (micro-LED), or a nano-LED, however, the present disclosure should not be limited thereto or thereby. According to an embodiment, the light emitting elements OLED may include various embodiments as long as they emit lights or control an amount of lights in response to electrical signals.

Each of the light emitting elements OLED may be electrically connected to a corresponding transistor of the corresponding pixel driving circuit PDC (refer to FIG. 5). FIGS. 6A and 6B show the structure in which each of the light emitting elements OLED is electrically connected to a corresponding sixth transistor T6 as a representative example.

The first electrodes AE of the light emitting elements OLED may be disposed at an uppermost position of the circuit element layer DP-CL. As an example, the first electrodes AE may be disposed on the seventh insulating layer 70. The first electrodes AE may be disposed spaced apart from each other on the seventh insulating layer 70, in a direction along the circuit element layer DP-CL. The first electrodes AE may be connected to a corresponding second connection electrode CNE2, via a contact hole defined through the seventh insulating layer 70. The first electrodes AE may be electrically connected to the sixth drain D6 by a corresponding second connection electrode CNE2 and a corresponding first-first connection electrode CNE11.

The pixel definition layer PDL may be disposed at the uppermost position of the circuit element layer DP-CL. As an example, the pixel definition layer PDL may be disposed on the seventh insulating layer 70. The pixel definition layer PDL may be provided with or define light emitting openings PX-OP respectively overlapping the first electrodes AE and exposing a portion of a corresponding first electrode AE to outside the pixel definition layer PDL. That is, a solid portion of the pixel definition layer PDL may define the light emitting openings PX-OP.

In the present embodiment, areas of the first electrodes AE exposed through the light emitting openings PX-OP may respectively correspond to a light emitting area PXA among a plurality of light emitting areas PXA. That is, the display area D-DA of the display panel DP may include the light emitting areas PXA. An area in which a solid portion of the pixel definition layer PDL is disposed may correspond to a non-light-emitting area NPXA. When viewed in the plane, the non-light-emitting area NPXA may be adjacent to and surround the light emitting areas PXA and may define a boundary of the light emitting areas PXA.

The pixel definition layer PDL may include a polymer resin. As an example, the pixel definition layer PDL may include a polyacrylate-based resin or a polyimide-based resin, however, the present disclosure should not be limited thereto or thereby. According to an embodiment, the pixel definition layer PDL may further include an inorganic material.

The pixel definition layer PDL may further include a light absorbing material. The pixel definition layer PDL may include a black coloring agent such as a black pigment or a black dye. As an example, the black coloring agent may include a metal material, such as carbon black, chrome, etc., or an oxide thereof. However, the pixel definition layer PDL should not be limited thereto or thereby.

The light emitting layer EM may be disposed on the first electrode AE. The light emitting layers EM of the light emitting elements OLED may include light emitting patterns respectively disposed in the light emitting openings PX-OP and spaced apart from each other in a direction along the display element layer DP-OLED when viewed in the plane, however, the present disclosure should not be limited thereto or thereby. According to an embodiment, the light emitting layers EM of the light emitting elements OLED may be provided in a common layer integrally formed.

The light emitting layer EM may include an organic light emitting material and/or an inorganic light emitting material. As an example, the light emitting layer EM may include a fluorescent material, a phosphorescent material, an organometallic complex light emitting material, or a quantum dot. The light emitting layer EM may emit a color light having one of red, green, and blue colors.

The second electrode CE may be disposed on the light emitting layer EM. The second electrode CE of the light emitting elements OLED may be provided in a common layer integrally formed and may overlap the light emitting areas PXA and the non-light-emitting area NPXA. The second electrode CE may be commonly disposed in the pixels PX (refer to FIG. 4) and may receive a common voltage.

The light emitting elements OLED may further include a light emitting control layer disposed between the first electrode AE and the second electrode CE. As an example, the light emitting control layer may include a hole control layer disposed between the first electrode AE and the light emitting layer EM or an electron control layer disposed between the light emitting layer EM and the second electrode CE. The hole control layer may include a hole injection layer, a hole transport layer, or an electron blocking layer, and the electron control layer may include an electron injection layer, an electron transport layer, or a hole blocking layer.

The encapsulation layer TFE may be disposed on the display element layer DP-OLED and may encapsulate the light emitting elements OLED. The encapsulation layer TFE may include at least one layer of an inorganic layer and an organic layer. According to an embodiment, the encapsulation layer TFE may include inorganic layers and an organic layer which is disposed between the inorganic layers.

The inorganic layer of the encapsulation layer TFE may protect the light emitting elements OLED from moisture and/or oxygen. As an example, the inorganic layer may include at least one of aluminum oxide, titanium oxide, silicon oxide, silicon nitride, silicon oxynitride, zirconium oxide, and hafnium oxide, however, the inorganic layer should not be limited thereto or thereby.

The organic layer of the encapsulation layer TFE may protect the light emitting elements OLED from a foreign substance, such as dust particles. The organic layer may include an acrylic-based resin, however, the organic layer should not be limited thereto or thereby.

The first driving voltage ELVDD (refer to FIG. 5) and the second driving voltage ELVSS (refer to FIG. 5) may be respectively applied to the first electrode AE and the second electrode CE. Holes and electrons, which are injected into the light emitting layer EM, may be recombined with each other to generate excitons, and the light emitting elements OLED may emit a light when the excitons return to a ground state from an excited state. The light emitting elements OLED may emit the light in response to electrical signals applied thereto, and thus, the display panel DP may display the image through the display area D-DA.

FIGS. 7A to 7G are plan views respectively showing patterned layers forming or providing a stacked structure of the pixel PXᵢⱼ (refer to FIG. 5). The views in FIGS. 7A to 7G are provided in the order in which the patterned layers are provided.

The circuit element layer DP-CL (refer to FIG. 6A) may include the semiconductor pattern layer and the conductive pattern layer, each provided in plural including a plurality of semiconductor pattern layers and a plurality of conductive pattern layers. Each of the semiconductor pattern layer and the conductive pattern layer may include patterns arranged in a predetermined rule when viewed in the plane. Each of the patterns may be discrete pattern, without being limited thereto. The patterns may form the pixel driving circuit PDC (refer to FIG. 5) and the signal lines among various features of the pixels. FIGS. 7A to 7G show the pixel driving circuits PDC (refer to FIG. 5) of the pixels PXᵢⱼ (refer to FIG. 5) which are adjacent to each other in a direction along the circuit element layer DP-CL.

Referring to FIG. 7A, the first semiconductor pattern layer SM1 may include or define first, second, fifth, sixth, and seventh semiconductor patterns SP1, SP2, SP5, SP6, and SP7. The first semiconductor pattern layer SM1 may be disposed on the base substrate SUB (refer to FIG. 6A) and may include the semiconductor material. As an example, the first semiconductor pattern layer SM1 may include amorphous silicon or polycrystalline silicon.

The first semiconductor pattern layer SM1 may include a plurality of regions doped with different concentrations. Among the regions of the first semiconductor pattern layer SM1, the region having the relatively high conductivity may correspond to the source or the drain of the respective transistor, and the region having the relatively low conductivity may correspond to the channel of the respective transistor.

The first semiconductor pattern SP1 may include a first source S1, a first drain D1, and a first channel A1. The second semiconductor pattern SP2 may include a second source S2, a second drain D2, and a second channel A2. The fifth semiconductor pattern SP5 may include a fifth source S5, a fifth drain D5, and a fifth channel A5. The sixth semiconductor pattern SP6 may include the sixth source S6, the sixth drain D6, and the sixth channel A6. The seventh semiconductor pattern SP7 may include a seventh source S7, a seventh drain D7, and a seventh channel A7. The first, second, fifth, sixth, and seventh channels A1, A2, A5, A6, and A7 may be respectively disposed between the first, second, fifth, sixth, and seventh sources S1, S2, S5, S6, and S7 and the first, second, fifth, sixth, and seventh drains D1, D2, D5, D6, and D7.

The first, second, fifth, sixth, and seventh semiconductor patterns SP1, SP2, SP5, SP6, and SP7 forming elements of the pixel driving circuit PDC (refer to FIG. 5) may be arranged in the first direction DR1 and the second direction DR2 when viewed in the plane. In the first direction DR1, the first, second, fifth, sixth, and seventh semiconductor patterns SP1, SP2, SP5, SP6, and SP7 forming one pixel driving circuit (e.g., a first pixel driving circuit) may be arranged in a symmetrical manner with respect to the semiconductor patterns forming another pixel driving circuit (e.g., a second pixel driving circuit) which is adjacent to (or closest to) the one pixel driving circuit. While this arrangement may be repeated, however, the arrangement of pixel driving circuits is not be limited thereto or thereby. According to an embodiment, the first, second, fifth, sixth, and seventh semiconductor patterns SP1, SP2, SP5, SP6, and SP7 forming one pixel driving circuit may have the same arrangement as that of the semiconductor patterns forming another pixel driving circuit adjacent thereto (e.g., a non-symmetrical manner), and this structure may be repeated in the first direction DR1.

The first semiconductor pattern SP1 may be connected to the second semiconductor pattern SP2, the fifth semiconductor pattern SP5, and the sixth semiconductor pattern SP6. The first source S1 of the first semiconductor pattern SP1 and the second drain D2 of the second semiconductor pattern SP2 may be formed integrally with each other and may be electrically connected to each other. The first source S1 of the first semiconductor pattern SP1 and the fifth drain D5 of the fifth semiconductor pattern SP5 may be formed integrally with each other and may be electrically connected to each other. A point where the first semiconductor pattern SP1, the second semiconductor pattern SP2, and the fifth semiconductor pattern SP5 are commonly connected to each other may correspond to the second node ND2 (refer to FIG. 5).

The first drain D1 of the first semiconductor pattern SP1 and the sixth source S6 of the sixth semiconductor pattern SP6 may be formed integrally with each other and may be electrically connected to each other. A point where the first semiconductor pattern SP1 and the sixth semiconductor pattern SP6 are commonly connected to each other may correspond to the third node ND3 (refer to FIG. 5).

The sixth drain D6 of the sixth semiconductor pattern SP6 and the seventh source S7 of the seventh semiconductor pattern SP7 may be formed integrally with each other and may be electrically connected to each other. A point where the sixth semiconductor pattern SP6 and the seventh semiconductor pattern SP7 are commonly connected to each other may correspond to the fourth node ND4 (refer to FIG. 5). Together, the first, second, fifth, sixth, and seventh semiconductor patterns SP1, SP2, SP5, SP6, and SP7 may form a single, continuous discrete pattern.

Referring to FIG. 7B, the first conductive pattern layer MP1 may be disposed on the first semiconductor pattern layer SM1 of FIG. 7A. An insulating layer, e.g., the first insulating layer 10 of FIG. 6A, may be disposed between the first conductive pattern layer MP1 and the first semiconductor pattern layer SM1 (refer to FIG. 7A). The first conductive pattern layer MP1 may include a first gate electrode G1, an emission line EL, and a first scan line GW.

The first gate electrode G1 may be disposed on the first semiconductor pattern SP1. The first gate electrode G1 may overlap the first channel A1 when viewed in the plane. The first semiconductor pattern SP1 and the first gate electrode G1 may form the first transistor T1, and the first gate electrode G1 may correspond to a first gate of the first transistor T1.

The emission line EL may extend in the first direction DR1 and may overlap the fifth semiconductor pattern SP5 and the sixth semiconductor pattern SP6 when viewed in the plane. A portion of the emission line EL, which overlaps the fifth semiconductor pattern SP5, may correspond to a fifth gate electrode G5 of the fifth transistor T5, and another portion of the emission line EL, which overlaps the sixth semiconductor pattern SP6, may correspond to the sixth gate electrode G6 of the sixth transistor T6. When viewed in the plane, the fifth gate electrode G5 may overlap the fifth channel A5 (refer to FIG. 7A), and the sixth gate electrode G6 may overlap the sixth channel A6 (refer to FIG. 7A).

The first scan line GW may extend in the first direction DR1 and may be spaced apart from the emission line EL in the second direction DR2. The first scan line GW may overlap the second semiconductor pattern SP2 and the seventh semiconductor pattern SP7 when viewed in the plane. A portion of the first scan line GW, which overlaps the second semiconductor pattern SP2, may correspond to a second gate electrode G2 of the second transistor T2, and another portion of the first scan line GW, which overlaps the seventh semiconductor pattern SP7, may correspond to a seventh gate electrode G7 of the seventh transistor T7. When viewed in the plane, the second gate electrode G2 may overlap the second channel A2 (refer to FIG. 7A), and the seventh gate electrode G7 may overlap the seventh channel A7 (refer to FIG. 7A).

The first conductive pattern layer MP1 may include a metal, alloy, conductive metal oxide, or transparent conductive material. As an example, the first conductive pattern layer MP1 may include silver (Ag), an alloy containing silver (Ag), molybdenum (Mo), an alloy containing molybdenum (Mo), aluminum (Al), an alloy containing aluminum (Al), aluminum nitride (AlN), tungsten (W), tungsten nitride (WN), copper (Cu), indium tin oxide (ITO), indium zinc oxide (IZO), or the like, however, should not be particularly limited. Descriptions about the material included in the first conductive pattern layer MP1 may be applied to other conductive pattern layers described later.

Referring to FIG. 7C, the second conductive pattern layer MP2 may be disposed on the first conductive pattern layer MP1 of FIG. 7B. An insulating layer, e.g., the second insulating layer 20 of FIG. 6B, may be disposed between the second conductive pattern layer MP2 and the first conductive pattern layer MP1 (refer to FIG. 7B). The second conductive pattern layer MP2 may include the upper electrode UE, a sub-second scan line GCa, a sub-third scan line GIa, and a first initialization line VIL1.

The upper electrode UE may be disposed to overlap the first gate electrode G1 (refer to FIG. 7B). The upper electrode UE may form the capacitor CAP (refer to FIG. 5) together with first gate electrode G1 (refer to FIG. 7B) overlapping the upper electrode UE. The upper electrode UE overlapping the first gate electrode G1 (refer to FIG. 7B) may correspond to the first electrode of the capacitor CAP (refer to FIG. 5), and the first gate electrode G1 (refer to FIG. 7B) overlapping the upper electrode UE may correspond to the second electrode of the capacitor CAP (refer to FIG. 5). The first electrode of the capacitor CAP (refer to FIG. 5) may be formed integrally with and may be electrically connected with the first gate electrode G1 (refer to FIG. 7B).

The upper electrode UE may be provided with or define an opening UE-O defined therethrough. In the plan view, the opening UE-O is an enclosed opening defined by a solid portion of the upper electrode UE. A portion of the first gate electrode G1 (refer to FIG. 7B) may be exposed to outside the second conductive pattern layer MP2, at the upper electrode UE, through the opening UE-O of the upper electrode UE.

The sub-second scan line GCa may extend in the first direction DR1. The sub-second scan line GCa may correspond to the second scan line GCi (refer to FIG. 5) to which the compensation scan signal GCSi (refer to FIG. 5) is applied. According to an embodiment, the second scan line GCi (refer to FIG. 5) may include two layers that receive the same signal (e.g., a same electrical signal), and the sub-second scan line GCa may be a portion of the two layers, however, should not be limited thereto or thereby. According to an embodiment, the second scan line GCi (refer to FIG. 5) may have a single-layer structure.

The sub-third scan line GIa may extend in the first direction DR1 and may be spaced apart from the sub-second scan line GCa in the second direction DR2. The sub-third scan line GIa may correspond to the third scan line GIi (refer to FIG. 5) to which the initialization scan signal GISi (refer to FIG. 5) is applied. According to an embodiment, the third scan line GIi (refer to FIG. 5) may include two layers that receive the same signal, and the sub-third scan line GIa may be a portion of the two layers, however, should not be limited thereto or thereby. According to an embodiment, the third scan line GIi (refer to FIG. 5) may have a single-layer structure.

The first initialization line VIL1 may extend in the first direction DR1 and may be spaced apart from the sub-second scan line GCa and the sub-third scan line GIa in the second direction DR2. The first initialization voltage Vint1 may be applied to the first initialization line VIL1.

Referring to FIG. 7D, the second semiconductor pattern layer SM2 may be disposed on the second conductive pattern layer MP2 of FIG. 7C. An insulating layer, e.g., the third insulating layer 30 of FIG. 6A, may be disposed between the second semiconductor pattern layer SM2 and the second conductive pattern layer MP2 (refer to FIG. 7C). The second semiconductor pattern layer SM2 may include the third semiconductor pattern SP3 and a fourth semiconductor pattern SP4. The second semiconductor pattern layer SM2 may include the semiconductor material. As an example, the second semiconductor pattern layer SM2 may include the semiconductor material different from the first semiconductor pattern layer SM1 (refer to FIG. 7A). As an example, the second semiconductor pattern layer SM2 may include a metal oxide, and the first semiconductor pattern layer SM1 (refer to FIG. 7A) may include silicon. However, the present disclosure should not be limited thereto or thereby as long as the second semiconductor pattern layer SM2 includes the semiconductor material.

The second semiconductor pattern layer SM2 may include the plural areas having different conductivities depending on whether the metal oxide is reduced or not. The area of the second semiconductor pattern layer SM2, which has the relatively higher conductivity, may correspond to the source or the drain of the respective transistor, and the area of the second semiconductor pattern layer SM2, which has the relatively lower conductivity, may correspond to the channel of the respective transistor.

The third semiconductor pattern SP3 may include the third source S3, the third drain D3, and the third channel A3. The third channel A3 may be disposed between the third source S3 and the third drain D3. The fourth semiconductor pattern SP4 may include a fourth source S4, a fourth drain D4, and a fourth channel A4. The fourth channel A4 may be disposed between the fourth source S4 and the fourth drain D4.

The third and fourth semiconductor patterns SP3 and SP4 forming the pixel driving circuit PDC (refer to FIG. 5) may be arranged in the first direction DR1 and the second direction DR2 when viewed in the plane. The third and fourth semiconductor patterns SP3 and SP4 forming one pixel driving circuit may be arranged in a symmetrical manner with respect to the semiconductor patterns forming another pixel driving circuit adjacent to (or closest to) the one pixel driving circuit. This structure along the first direction DR1 may be repeated, however, should not be limited thereto or thereby. According to an embodiment, the third and fourth semiconductor patterns SP3 and SP4 forming one pixel driving circuit may have the same arrangement as that of the semiconductor patterns forming another pixel driving circuit adjacent thereto, and this structure may be repeated in the first direction DR1.

The third semiconductor pattern SP3 may be connected to the fourth semiconductor pattern SP4. The third source S3 of the third semiconductor pattern SP3 and the fourth drain D4 of the fourth semiconductor pattern SP4 may be integrally formed with each other and may be electrically connected to each other. A point where the third semiconductor pattern SP3 is connected to the fourth semiconductor pattern SP4 may correspond to the first node ND1 (refer to FIG. 5).

At least a portion of the third semiconductor pattern SP3 may overlap the first conductive pattern layer MP1 (refer to FIG. 7B) or the second conductive pattern layer MP2 (refer to FIG. 7C) when viewed in the plane. The third channel A3 of the third semiconductor pattern SP3 may overlap the sub-second scan line GCa disposed under the third channel A3. The portion of the sub-second scan line GCa, which overlaps the third channel A3, may correspond to a third gate. In addition, portions of the first scan line GW and the sub-second scan line GCa, which overlap the third semiconductor pattern SP3, may protect the third semiconductor pattern SP3 from the light incident thereto from a lower side of the display panel.

At least a portion of the fourth semiconductor pattern SP4 may overlap the first conductive pattern layer MP1 (refer to FIG. 7B) or the second conductive pattern layer MP2 (refer to FIG. 7C) when viewed in the plane. The fourth channel A4 of the fourth semiconductor pattern SP4 may overlap the sub-third scan line GIa disposed under the fourth channel A4. A portion of the sub-third scan line GIa, which overlaps the fourth channel A4, may correspond to a fourth gate. In addition, portions of the sub-third scan line GIa and the first initialization line VIL1, which overlap the fourth semiconductor pattern SP4, may protect the fourth semiconductor pattern SP4 from a light incident thereto from the lower side of the display panel.

Referring to FIG. 7E, the third conductive pattern layer MP3 may be disposed on the second semiconductor pattern layer SM2 of FIG. 7D. An insulating layer, e.g., the fourth insulating layer 40 of FIG. 6A, may be disposed between the third conductive pattern layer MP3 and the second semiconductor pattern layer SM2 (refer to FIG. 7D). The third conductive pattern layer MP3 may include a sub-second scan line GCb and a sub-third scan line GIb.

The sub-second scan line GCb may extend in the first direction DR1. The sub-second scan line GCb may correspond to the second scan line GCi (refer to FIG. 5) to which the compensation scan signal GCSi (refer to FIG. 5) is applied. The sub-second scan line GCb of the third conductive pattern layer MP3 and the sub-second scan line GCa of the second conductive pattern layer MP2 (refer to FIG. 7C) may overlap each other when viewed in the plane. The sub-second scan lines GCa and GCb disposed on different layers from each other may be electrically connected to each other and may receive the same signal. That is, according to an embodiment, the second scan line GCi (refer to FIG. 5) may be a line including two layers to which the same signal is applied, and the sub-second scan line GCb may be a portion of the two layers. However, the present disclosure should not be limited thereto or thereby, and one of the sub-second scan lines GCa and GCb may be omitted.

The sub-second scan line GCb of the third conductive pattern layer MP3 may overlap the third semiconductor pattern SP3 when viewed in the plane. A portion of the sub-second scan line GCb, which overlaps the third semiconductor pattern SP3, may correspond to the third gate electrode G3 of the third transistor T3. When viewed in the plane, the third gate electrode G3 may overlap the third channel A3 (refer to FIG. 7D). The third channel A3 (refer to FIG. 7D) may overlap each of the sub-second scan line GCa disposed under the third semiconductor pattern SP3 and the sub-second scan line GCb disposed on the third semiconductor pattern SP3. Accordingly, the third gate of the third transistor T3 may be formed to have a two-layer structure, may have a sufficient gate charge amount, and may be switched at high speed.

The sub-third scan line GIb may extend in the first direction DR1. The sub-third scan line GIb may correspond to the third scan line GIi (refer to FIG. 5) to which the initialization scan signal GISi (refer to FIG. 5) is applied. The sub-third scan line GIb of the third conductive pattern layer MP3 and the sub-third scan line GIa of the second conductive pattern layer MP2 (refer to FIG. 7C) may overlap each other when viewed in the plane. The sub-third scan lines GIa and GIb disposed on different layers from each other may be electrically connected to each other and may receive the same signal. That is, according to an embodiment, the third scan line GIi (refer to FIG. 5) may be a line including two layers to which the same signal is applied, and the sub-third scan line GIb may be a portion of the two layers. However, the present disclosure should not be limited thereto or thereby, and one of the sub-third scan lines GIa and GIb may be omitted.

The sub-third scan line GIb of the third conductive pattern layer MP3 may overlap the fourth semiconductor pattern SP4 when viewed in the plane. A portion of the sub-third scan line GIb, which overlaps the fourth semiconductor pattern SP4, may correspond to a fourth gate electrode G4 of the fourth transistor T4. When viewed in the plane, the fourth gate electrode G4 may overlap the fourth channel A4. The fourth channel A4 may overlap each of the sub-third scan line GIa disposed under the fourth semiconductor pattern SP4 and the sub-third scan line GIb disposed on the fourth semiconductor pattern SP4. Accordingly, the fourth gate of the fourth transistor T4 may be formed to have the two-layer structure, may have a sufficient gate charge amount, and may be switched at high speed.

Referring to FIG. 7F, the fourth conductive pattern layer MP4 may be disposed on the third conductive pattern layer MP3 of FIG. 7E. An insulating layer, e.g., the fifth insulating layer 50 of FIG. 6A, may be disposed between the fourth conductive pattern layer MP4 and the third conductive pattern layer MP3 (refer to FIG. 7E). The fourth conductive pattern layer MP4 may include the connection electrodes CNE11 to CNE13 and connection electrodes CNE14 to CNE17 disposed on the same layer and spaced apart from each other.

The connection electrodes CNE11 to CNE17 may electrically connect components connected thereto. Each of the connection electrodes CNE11 to CNE17 may overlap components connected thereto when viewed in the plane. The connection electrodes CNE11 to CNE17 may be connected to the components through at least one insulating layer disposed between the connection electrode and the component. The connection electrodes CNE11 to CNE17 may include the first-first to first-seventh connection electrodes CNE11 to CNE17.

The first-first connection electrode CNE11 may overlap the sixth semiconductor pattern SP6 (refer to FIG. 7B) of the sixth transistor T6. The first-first connection electrode CNE11 may be connected to the sixth drain D6 (refer to FIG. 7A) of the sixth transistor T6 through a contact hole. The first-first connection electrode CNE11 may electrically connect the first electrode AE (refer to FIG. 6A) of the light emitting element OLED (refer to FIG. 6A) disposed on the first-first connection electrode CNE11 and the sixth transistor T6.

The first-second connection electrode CNE12 may overlap each of the first semiconductor pattern SP1 (refer to FIG. 7B) of the first transistor T1 and the third semiconductor pattern SP3 (refer to FIG. 7D) of the third transistor T3. The first-second connection electrode CNE12 may be connected to the first drain D1 (refer to FIG. 7A) of the first transistor T1 and the third drain D3 (refer to FIG. 7D) of the third transistor T3 through a contact hole. The first drain D1 (refer to FIG. 7A) of the first transistor T1 and the third drain D3 (refer to FIG. 7D) of the third transistor T3, which are disposed on different layers from each other, may be electrically connected to each other by the first-second connection electrode CNE12. A point where the first transistor T1, the third transistor T3, and the sixth transistor T6 are electrically connected to each other may correspond to the third node ND3 (refer to FIG. 5).

The first-third connection electrode CNE13 may overlap each of the first gate electrode G1 (refer to FIG. 7B) of the first transistor T1 and the third semiconductor pattern SP3 (refer to FIG. 7D) of the third transistor T3. The first-third connection electrode CNE13 may be connected to the first gate electrode G1 (refer to FIG. 7B) via the opening UE-O of the upper electrode UE. The first-third connection electrode CNE13 may be connected to the third source S3 (refer to FIG. 7D) of the third transistor T3. The first gate electrode G1 (refer to FIG. 7B) of the first transistor T1 and the third source S3 (refer to FIG. 7D) of the third transistor T3, which are disposed on different layers from each other, may be electrically connected to each other by the first-third connection electrode CNE13. A point where the first gate electrode G1 (refer to FIG. 7B) of the first transistor T1 is electrically connected to the third source S3 (refer to FIG. 7D) of the third transistor T3 may correspond to the first node ND1 (refer to FIG. 5).

The first-fourth connection electrode CNE14 may overlap each of the upper electrode UE and the fifth semiconductor pattern SP5 (refer to FIG. 7B) of the fifth transistor T5. The first-fourth connection electrode CNE14 may be connected to the upper electrode UE and the fifth source S5 (refer to FIG. 7A) of the fifth transistor T5. That is, the first-fourth connection electrode CNE14 may be electrically connected to the upper electrode UE corresponding to the first electrode of the capacitor CAP (refer to FIG. 5). The first-fourth connection electrode CNE14 may be connected to the first voltage line VL1 (refer to FIG. 5) disposed on the first-fourth connection electrode CNE14. That is, the upper electrode UE and the fifth source S5 (refer to FIG. 7A) of the fifth transistor T5 may be electrically connected to the first voltage line VL1 (refer to FIG. 5) via the first-fourth connection electrode CNE14 and may receive the first driving voltage ELVDD (refer to FIG. 5).

The first-fifth connection electrode CNE15 may overlap the seventh semiconductor pattern SP7 (refer to FIG. 7B) of the seventh transistor T7. The first-fifth connection electrode CNE15 may be connected to the seventh source S7 (refer to FIG. 7A) of the seventh transistor T7. The first-fifth connection electrode CNE15 may be connected to the second initialization line VIL2 (refer to FIG. 5) disposed on the first-fifth connection electrode CNE15. That is, the seventh source S7 (refer to FIG. 7A) of the seventh transistor T7 may be electrically connected to the second initialization line VIL2 (refer to FIG. 5) by the first-fifth connection electrode CNE15 and may receive the second initialization voltage Vint2 (refer to FIG. 5).

The first-sixth connection electrode CNE16 may overlap the second semiconductor pattern SP2 (refer to FIG. 7B) of the second transistor T2. The first-sixth connection electrode CNE16 may be connected to the second source S2 (refer to FIG. 7A) of the second transistor T2. The first-sixth connection electrode CNE16 may be connected to the data line DLj (refer to FIG. 5) disposed on the first-sixth connection electrode CNE16. That is, the second source S2 (refer to FIG. 7A) of the second transistor T2 may be electrically connected to the data line DLj (refer to FIG. 5) via the first-sixth connection electrode CNE16 and may receive the data voltage Vd (refer to FIG. 5).

The first-seventh connection electrode CNE17 may overlap the fourth semiconductor pattern SP4 (refer to FIG. 7D) of the fourth transistor T4. The first-seventh connection electrode CNE17 may be connected to the fourth source S4 (refer to FIG. 7D) of the fourth transistor T4. The first-seventh connection electrode CNE17 may be connected to the first initialization line VIL1 (refer to FIG. 5) via a wiring or a connection electrode disposed on the first-seventh connection electrode CNE17. That is, the fourth source S4 (refer to FIG. 7D) of the fourth transistor T4 may be electrically connected to the first initialization line VIL1 (refer to FIG. 5) via the first-seventh connection electrode CNE17 and may receive the first initialization voltage Vint1 (refer to FIG. 5).

The display panel DP (refer to FIG. 6A) may include at least one anti-shock portion disposed corresponding to the pixel driving circuit PDC (refer to FIG. 5). FIG. 7F shows the structure in which first, second, and third anti-shock portions CP1, CP2, and CP3 are disposed corresponding to one pixel driving circuit PDC (refer to FIG. 5) as a representative example, however, the number of the anti-shock portions in one pixel driving circuit PDC (refer to FIG. 5) should not be limited thereto or thereby.

The first to third anti-shock portions CP1 to CP3 may be formed through at least one insulating layer included in the circuit element layer DP-CL (refer to FIG. 6A). Through holes in which the first to third anti-shock portions CP1 to CP3 are disposed may be formed through a process of forming the contact holes overlapping the connection electrodes CNE11 to CNE17.

The first to third anti-shock portions CP1 to CP3 may be formed by filling a metal material with a relatively high modulus in the through hole defined through at least one insulating layer included in the circuit element layer DP-CL (refer to FIG. 6A). As an example, each of the first to third anti-shock portions CP1 to CP3 may have the modulus equal to or greater than about 100 GPa.

According to an embodiment, the first to third anti-shock portions CP1 to CP3 may be substantially simultaneously formed with a plurality of first connection electrode including the connection electrodes CNE11 to CNE17 through the same process. As an example, the first to third anti-shock portions CP1 to CP3 may be disposed on the same layer as and may include the same material as the connection electrodes CNE11 to CNE17. Accordingly, a process of forming the first to third anti-shock portions CP1 to CP3 and a mask may be omitted, and the first to third anti-shock portions CP1 to CP3 may be formed through a simplified process.

However, the present disclosure should not be limited thereto or thereby. According to an embodiment, the through holes in which the first to third anti-shock portions CP1 to CP3 are disposed and the contact holes in which the connection electrodes CNE11 to CNE17 are disposed may be substantially simultaneously formed, however, the first to third anti-shock portions CP1 to CP3 may include a material different from a material of the connection electrodes CNE11 to CNE17. According to an embodiment, the through holes in which the first to third anti-shock portions CP1 to CP3 are disposed may be formed through a separate process from the contact holes in which the connection electrodes CNE11 to CNE17 are disposed. A modulus of the material included in the first to third anti-shock portions CP1 to CP3 may exert an influence on improvement of the anti-impact resistance of the display panel DP (refer to FIG. 6A). Accordingly, materials used to form the first to third anti-shock portions CP1 to CP3 may be designed by taking into account the anti-impact resistance required for the display panel DP (refer to FIG. 6A).

The first to third anti-shock portions CP1 to CP3 may be formed at a location that does not affect the driving of the pixel within the pixel driving circuit PDC (refer to FIG. 5). As a result, the first to third anti-shock portions CP1 to CP3 may not affect electrical characteristics of the pixels. Accordingly, the first to third anti-shock portions CP1 to CP3 may relieve the stress of the display panel DP (refer to FIG. 6A) and may prevent the disconnection or short-circuit between components in the pixel driving circuit PDC (refer to FIG. 5).

The first anti-shock portion CP1 may overlap the upper electrode UE. The first anti-shock portion CP1 may be formed in an area corresponding to the first electrode of the capacitor CAP (refer to FIG. 5). The first anti-shock portion CP1 may be disposed in the through hole defined through at least a portion of the insulating layers disposed between the fourth conductive pattern layer MP4 and the upper electrode UE. The first anti-shock portion CP1 may not overlap the first source S1 (refer to FIG. 7A) and the first drain D1 (refer to FIG. 7A) of the first transistor T1. As a result, the first anti-shock portion CP1 may not affect the electrical characteristics and the driving of the first transistor T1, and the stress or the external impacts applied to the area adjacent to the first anti-shock portion CP1 may be relieved.

The second anti-shock portion CP2 may overlap the sub-second scan lines GCa and GCb. The sub-second scan lines GCa and GCb may receive the same electrical signal and may be electrically connected to each other to form the second scan line GC. The second anti-shock portion CP2 may be disposed in the through hole defined through at least a portion of the insulating layers disposed between the fourth conductive pattern layer MP4 and the sub-second scan lines GCa and GCb. According to an embodiment, the sub-second scan lines GCa and GCb may be electrically connected to each other via the second anti-shock portion CP2. As the second anti-shock portion CP2 is disposed to overlap the sub-second scan lines GCa and GCb receiving the same signal, the electrical characteristics and the driving of the second scan line GC and the elements electrically connected to the second scan line GC may not be affected, and the stress or external impacts applied to the area adjacent to the second anti-shock portion CP2 may be relieved.

The second anti-shock portion CP2 may be disposed adjacent to the second transistor T2. The second anti-shock portion CP2 may relieve the stress or external impacts applied to the area adjacent to the second transistor T2. As a result, the second transistor T2 may be prevented from being damaged due to the stress or external impacts. In a case where the second transistor T2 defined as the switching transistor in the pixel driving circuit PDC (refer to FIG. 5) is damaged, the defect such as the bright spot may occur in the pixel. However, as the second anti-shock portion CP2 reduces and relieves the propagation of the external impacts in the area adjacent to the second transistor T2, the damage on the second transistor T2 may be prevented, and as a result, the reliability of the display panel DP (refer to FIG. 6A) may be improved.

The third anti-shock portion CP3 may overlap the sub-third scan lines GIa and GIb. The sub-third scan lines GIa and GIb may be wirings receiving the same electrical signal and may be electrically connected to each other to form the third scan line GI. The third anti-shock portion CP3 may be disposed in the through hole defined through at least a portion of the insulating layers disposed between the fourth conductive pattern layer MP4 and the sub-third scan lines GIa and GIb. According to an embodiment, the sub-third scan lines GIa and GIb may be electrically connected to each other via the third anti-shock portion CP3. As the third anti-shock portion CP3 is disposed to overlap the sub-third scan lines GIa and GIb receiving the same signal, the electrical characteristics and the driving of the third scan line GI and the elements electrically connected to the third scan line GI may not be affected, and the stress or external impacts applied to the area adjacent to the third anti-shock portion CP3 may be relieved.

The third anti-shock portion CP3 may be disposed adjacent to the third transistor T3. The third anti-shock portion CP3 may relieve the stress or external impacts applied to the area adjacent to the third transistor T3. As a result, the damage on the third transistor T3, which is caused by the stress or external impacts, may be prevented. In a case where the third transistor T3 defined as the compensation transistor is damaged in the pixel driving circuit PDC (refer to FIG. 5), the defect such as the bright spot may occur in the pixel. However, as the third anti-shock portion CP3 reduces and relieves the propagation of the external impacts in the area adjacent to the third transistor T3, the damage on the third transistor T3 may be prevented, and as a result, the reliability of the display panel DP (refer to FIG. 6A) may be improved.

The present embodiment shows the structure in which the first, second, and third anti-shock portions CP1, CP2, and CP3 are disposed in the display panel DP (refer to FIG. 6A) as a representative example, however, according to an embodiment, some of the first, second, and third anti-shock portions CP1, CP2, and CP3 may be omitted. According to an embodiment, the display panel DP (refer to FIG. 6A) may include more anti-shock portions.

In addition, the first to third anti-shock portions CP1 to CP3 respectively overlapping the upper electrode UE, the second scan line GC, and the third scan line GI are shown as a representative example, however, the positions of the anti-shock portions CP1 to CP3 should not be particularly limited as long as they do not affect the driving of the pixel.

Referring to FIG. 7G, the display panel DP (refer to FIG. 6B) may further include the shock absorption pattern OM disposed in the circuit element layer DP-CL (refer to FIG. 6B) as described above. The shock absorption pattern OM may be formed through at least a portion of the insulating layers of the circuit element layer DP-CL (refer to FIG. 6B). As an example, the shock absorption pattern OM may be disposed through at least a portion of the insulating layers disposed under the fourth conductive pattern layer MP4, e.g., the first to fifth insulating layers 10 to 50, as shown in FIG. 6B.

The shock absorption pattern OM may include a material with high flexibility. As an example, the shock absorption pattern OM may include an organic material. The shock absorption pattern OM may have the modulus lower than the modulus of each of the anti-shock portions CP1, CP2, and CP3.

The shock absorption pattern OM may be arranged to surround each pixel PX (refer to FIG. 4) or may be arranged to surround each group of the pixels PX (refer to FIG. 4) when viewed in the plane, where a pixel group includes a plurality of pixels PX. As an example, the shock absorption pattern OM may be disposed to surround an area corresponding to at least one pixel driving circuit PDC (refer to FIG. 5) when viewed in the plane. FIG. 7G shows a structure in which the shock absorption pattern OM surrounds two pixel driving circuits PDC (refer to FIG. 5) forming two pixels PX (refer to FIG. 4) as a representative example.

As the shock absorption pattern OM having the flexibility is disposed to surround a specific area in the circuit element layer DP-CL (refer to FIG. 6A), the shock absorption pattern OM may effectively absorb the external impacts applied to the area surrounded by the shock absorption pattern OM. As an example, the shock absorption pattern OM may absorb the external impacts applied to one pixel to prevent the external impacts from being transmitted to the one pixel and pixels adjacent to the one pixel. That is, the shock absorption pattern OM may prevent the external impacts from being transmitted successively to the adjacent pixels.

The shock absorption pattern OM may improve the anti-impact resistance of the display panel DP (refer to FIG. 6A) together with the anti-shock portions CP1, CP2, and CP3 and may relieve the stress caused by the folding operations and the external impacts. As the shock absorption pattern OM surrounding the specific area has a relatively low modulus, the shock absorption pattern OM absorbs the external impacts applied to the specific area. As the anti-shock portions CP1, CP2, and CP3 arranged locally in specific portions have a relatively high modulus, the stress around the anti-shock portions CP1, CP2, and CP3 may be relieved, and the propagation of the cracks may be prevented. As a result, the reliability of the display panel DP (refer to FIG. 6A) and the display device DD (refer to FIG. 1) including the display panel DP (refer to FIG. 6A) may be improved.

The shock absorption pattern OM may define a planar area including one or more pixel PX. The various anti-shock portions as discrete patterns, may be arranged within the planar area defined by the shock absorption pattern OM. That is, a shock absorbing layer may include a plurality of patterns each having a modulus, e.g., an elastic modulus. Additionally, an insulating layer through which a pattern of the shock absorbing layer penetrates has a modulus. The modulus of the shock absorption pattern OM is lower than the modulus of the anti-shock portion CP and the respective layer through which the shock absorption pattern OM.

The shapes and arrangements of the pattern layers forming the pixels shown in FIGS. 7A to 7G are merely examples and should not be particularly limited.

Although the embodiments of the present disclosure have been described, it is understood that the present disclosure should not be limited to these embodiments but various changes and modifications can be made by one ordinary skilled in the art within the spirit and scope of the present disclosure as hereinafter claimed.

Therefore, the disclosed subject matter should not be limited to any single embodiment described herein, and the scope of the present invention shall be determined according to the attached claims.

What is claimed is:

1. A display panel comprising:
a display area;
a circuit element layer comprising insulating layers and a transistor in the display area, a first insulating layer among the insulating layers defining a first through hole of the circuit element layer which is in the display area;
a light emitting element electrically connected to the transistor; and
an anti-shock pattern having an elastic modulus greater than about 100 gigapascals, the anti-shock pattern being in the first through hole.

2. The display panel of claim 1, wherein the anti-shock pattern comprises a metal material.

3. The display panel of claim 1, wherein the first insulating layer which defines the first through hole comprises an inorganic material.

4. The display panel of claim 1, wherein
the transistor comprises:
a semiconductor pattern comprising a source, a channel and a drain; and
a gate electrode on the semiconductor pattern, and
the anti-shock pattern does not overlap the source and the drain of the transistor.

5. The display panel of claim 1, wherein
the circuit element layer further comprises a connection electrode electrically connecting the transistor and the light emitting element to each other, and
the anti-shock pattern is on a same layer as the connection electrode.

6. The display panel of claim 5, wherein the anti-shock pattern comprises a same material as the connection electrode.

7. The display panel of claim 1, wherein the circuit element layer further comprises sub-scan lines which are on different layers from each other, overlap each other, and receive a same electrical signal.

8. The display panel of claim 7, wherein the anti-shock pattern overlaps the sub-scan lines.

9. The display panel of claim 1, wherein the circuit element layer further comprises:
a second insulating layer among the insulating layers which defines a second through hole of the circuit element layer which is in the display area; and
a shock absorption pattern penetrating the second through hole, the shock absorption pattern comprising an organic material.

10. The display panel of claim 9, wherein within the circuit element layer, the shock absorption pattern surrounds the transistor and the anti-shock pattern.

11. The display panel of claim 9, wherein an elastic modulus of the shock absorption pattern in the second through hole is lower than the elastic modulus of the anti-shock pattern in the first through hole.

12. A display panel comprising:
a base substrate;
in order from the base substrate:
a first semiconductor pattern layer;
a first insulating layer;
a first conductive pattern layer;
a second insulating layer;
a second conductive pattern layer;
a third insulating layer; and
a light emitting element,
wherein at least one insulating layer among the first, second and third insulating layers defines a first through hole; and
an anti-shock pattern having an elastic modulus equal to or greater than about 100 gigapascals, the anti-shock pattern in the first through hole.

13. The display panel of claim 12, wherein
the first semiconductor pattern layer comprises a first semiconductor pattern of a first transistor, connected to the light emitting element, and
the first conductive pattern layer comprises a first gate electrode of the first transistor, the first gate electrode overlapping the first semiconductor pattern.

14. The display panel of claim 12, wherein the first to third insulating layers comprise an inorganic material.

15. The display panel of claim 12, further comprising between the third insulating layer and the light emitting element, in order from the third insulating layer:
a second semiconductor pattern layer;
a fourth insulating layer;
a third conductive pattern layer;
a fifth insulating layer; and
a fourth conductive pattern layer,
wherein at least one insulating layer among the first, second, third, fourth and fifth insulating layers defines the first through hole in which the anti-shock pattern is disposed.

16. The display panel of claim 15, wherein the first semiconductor pattern layer and the second semiconductor pattern layer comprise different semiconductor materials from each other.

17. The display panel of claim 15, wherein
the fifth insulating layer defines the first through hole, and
the anti-shock pattern is on a same layer as the fourth conductive pattern layer.

18. The display panel of claim 15, further comprising a shock absorption pattern comprising an organic material and having an elastic modulus lower than the elastic modulus of the anti-shock pattern,
wherein
at least one insulating layer among the first to fifth insulating layers defines a second through hole, and
the shock absorption pattern penetrates the second through hole.

19. A display panel comprising:
a display area;
a plurality of pixels in the display area, each of the pixels comprising a pixel driving circuit and a light emitting element which is electrically connected to the pixel driving circuit;
a planar area of the display area including the pixel driving circuit; and
a plurality of metal anti-shock patterns within the planar area of the display area, each of the metal anti-shock patterns having an elastic modulus equal to or greater than about 100 gigapascals.

20. The display panel of claim 19, further comprising an organic shock absorption pattern in the display area and having an elastic modulus lower than the elastic modulus of the anti-shock pattern, the organic shock absorption pattern surrounding the planar area of the display area which includes the pixel driving circuit.
